(19) United States
(12) Patent Application Publication
(10) Pub. No.: US 2026/0236126 A1
(43) Pub. Date: Aug. 13, 2026

(54) SENSOR AND INPUT DEVICE COMPRISING SAME

(71) Applicant: HiDeep Inc., Seongnam-si, Gyeonggi-do (KR)

(72) Inventors: Seyeob KIM, Seongnam-si, Gyeonggi-do (KR); Bonkee KIM, Seongnam-si, Gyeonggi-do (KR)

(73) Assignee: HiDeep Inc., Seongnam-si, Gyeonggi-do (KR)

(21) Appl. No.: 19/159,234

(22) PCT Filed: Feb. 2, 2024
(86) PCT No.: PCT/KR2024/001619

§ 371 Date: Aug. 22, 2025

(30) Foreign Application Priority Data
Feb. 24, 2023 (KR) 10-2023-0025266
Apr. 17, 2023 (KR) 10-2023-0050240
Jun. 1, 2023 (KR) 10-2023-0071015

(51) Int. Cl. G06F 3/044; G06F 3/041; G06F 3/047

(52) U.S. Cl. CPC G06F 3/0446; G06F 3/04164; G06F 3/0441; G06F 3/0448; G06F 3/047

(57) ABSTRACT

An embodiment of the present invention relates to a sensor and an input device comprising same. The sensor according to an embodiment of the present invention comprises: a first electrode including first electrode pattern portions and second electrode pattern portions that alternate at least one at a time along a first axis direction, and including a first electrode connection pattern portion for electrically connecting the first electrode pattern portions and a second electrode connection pattern portion for electrically connecting the second electrode pattern portions; and a second electrode including third electrode pattern portions and fourth electrode pattern portions that alternate at least one at a time along a second axis direction that is different from the first axis direction, and including a third electrode connection pattern portion for electrically connecting the third electrode pattern portions and a fourth electrode connection pattern portion for electrically connecting the fourth electrode pattern portions.

### TECHNICAL FIELD

The present invention relates to a sensor and an input device including same.

### BACKGROUND ART

Various kinds of input devices are used to operate a computing system. For example, the input devices such as a button, a key, a joystick, and a touch screen are used. Since the touch screen is easily and simply operated, the touch screen is increasingly used when operating the computing system.

A touch sensor that is one kind of information input devices may be provided and used in a display device. For example, the touch sensor may be attached to one surface of a display panel or integrated with the display panel. A user may input information by pressing or touching the touch sensor while watching an image displayed on a screen of the display device.

When a driving electrode and a receiving electrode of the touch sensor are implemented as a single layer or double layers, a phenomenon in which a signal that is normally detected by low ground mass (LGM) when a touch input device to which the touch sensor is mounted is touched in a state (floating state) in which the touch input device is not held by hands is disappeared or a signal to be detected is split and touched at two points or more may occur.

### DISCLOSURE OF THE INVENTION

### Technical Problem

The present invention provides a sensor capable of improving sensing sensitivity and an input device including same.

The present invention also provides a sensor capable of removing or improving noise in the sensor caused by driving of a display panel and an input device including same.

The present invention also provides a sensor capable of removing or improving noise in a display panel caused by driving of the sensor and an input device including the same.

The present invention also provides a sensor capable of removing or improving noise in the sensor in a low ground mass (LGM) state and an input device including same.

The present invention also provides a sensor capable of driving an external stylus pen or receiving a pen signal from an external stylus pen and an input device including same.

### Technical Solution

An embodiment of the present invention provide a sensor including: a first electrode including first electrode pattern portions and second electrode pattern portions, which are alternately arranged with at least one of each along a first axial direction, a first electrode connection pattern portion configured to electrically connect the first electrode pattern portions, and a second electrode connection pattern portion configured to electrically connect the second electrode pattern portions; and a second electrode including third electrode pattern portions and fourth electrode pattern portions, which are alternately arranged with at least one of each along a second axial direction, a third electrode connection pattern portion configured to electrically connect the third electrode pattern portions, and a fourth electrode connection pattern portion configured to electrically connect the fourth electrode pattern portions.

In an embodiment of the present invention, a sensor includes: a first electrode including first electrode pattern portions and second electrode pattern portions, which are alternately arranged with at least one of each along a first axis direction, a first electrode connection pattern portion electrically configured to electrically connect the first electrode pattern portions, and a second electrode connection pattern portion configured to electrically connect the second electrode pattern portions; a second electrode including third electrode pattern portions and fourth electrode pattern portions, which are alternately arranged with at least one of each along a second axis direction different from the first axis, a third electrode connection pattern portion configured to electrically connect the third electrode pattern portions, and a fourth electrode connection pattern portion configured to electrically connect the fourth electrode pattern portions; a first pen electrode disposed adjacent to the first electrode to form a first capacitive coupling with the first electrode; and a second pen electrode disposed adjacent to the second electrode to form a second capacitive coupling with the second electrode, in which each of the first electrode, the second electrode, the first pen electrode, and the second pen electrode is provided in plurality, one ends of the plurality of first pen electrodes are electrically connected to each other, and one ends of the plurality of second pen electrodes are electrically connected to each other.

In an embodiment of the present invention, an input device includes a sensor and a control unit configured to control the sensor, in which the sensor includes: a first electrode including first electrode pattern portions and second electrode pattern portions, which are alternately arranged with at least one of each along a first axial direction, a first electrode connection pattern portion configured to electrically connect the first electrode pattern portions, and a second electrode connection pattern portion configured to electrically connect the second electrode pattern portions; and a second electrode including third electrode pattern portions and fourth electrode pattern portions, which are alternately arranged with at least one of each along a second axial direction, a third electrode connection pattern portion configured to electrically connect the third electrode pattern portions, and a fourth electrode connection pattern portion configured to electrically connect the fourth electrode pattern portions, and the control unit includes: a driving unit configured to apply at least one driving signal to one of the first electrode and the second electrode; a sensing unit configured to receive at least one sensing signal from one of the first electrode and the second electrode; and a control unit configured to determine a touch position based on a signal output from the sensing unit.

In an embodiment of the present invention, an input device includes: a sensor; and a control unit configured to control the sensor, in which the sensor includes: a first electrode including first electrode pattern portions and second electrode pattern portions, which are alternately arranged with at least one of each along a first axis direction, a first electrode connection pattern portion configured to electrically connect the first electrode pattern portions, and a second electrode connection pattern portion configured to electrically connect the second electrode pattern portions; a second electrode including third electrode pattern portions and fourth electrode pattern portions, which are alternately arranged with at least one of each along a second axial direction, a third electrode connection pattern portion configured to electrically connect the third electrode pattern portions, and a fourth electrode connection pattern portion configured to electrically connect the fourth electrode pattern portions; a first pen electrode disposed adjacent to the first electrode to form a first capacitive coupling with the first electrode; and a second pen electrode disposed adjacent to the second electrode to form a second capacitive coupling with the second electrode, in which each of the first electrode, the second electrode, the first pen electrode, and the second pen electrode is provided in plurality, one ends of the plurality of first pen electrodes are electrically connected to each other, and one ends of the plurality of second pen electrodes are electrically connected to each other, in which the controller includes: a driving unit configured to apply a touch driving signal to the first electrode and a pen driving signal to at least one electrode among the first electrode, the second electrode, the first pen electrode, and the second pen electrode; and a sensing unit configured to receive a touch sensing signal from the second electrode and a pen sensing signal from at least two electrodes among the first electrode, the second electrode, the first pen electrode, and the second pen electrode, in which the control unit a control unit determines a touch position of an object and a position of a stylus pen based on a signal output from the sensing unit.

### Advantageous Effects

According to the embodiment of the present invention, the sensor and the input device including same may be used to improve the touch sensing sensitivity.

Also, the embodiments of the present invention may have the advantage of removing or improving the noise occurring in the sensor, which is caused by the driving of the display panel.

Also, the embodiments of the present invention may have the advantage of removing or improving the noise occurring in the display panel, which is caused by the driving of the sensor.

Also, the embodiments of the present invention may have the advantage of removing or improving the noise occurring in the sensor in the low ground mass (LGM) state.

Also, the embodiments of the present invention may have the advantage of driving the external stylus pen or receiving the pen signal from the external stylus pen to sense the position of the stylus pen.

### BRIEF DESCRIPTION OF THE DRAWINGS

FIG. 1 is a schematic view illustrating a sensor and an input device including same according to an embodiment of the present invention.

FIG. 2 is a plan view illustrating a portion of the sensor according to an embodiment of the sensor 10 in FIG. 1.

FIGS. 3A and 3B are plan views illustrating the sensor in FIG. 2, separated by layer.

FIG. 4 is a view for explaining a first driving method of the sensor in FIGS. 2 and 3 according to an embodiment of the present invention.

FIG. 5 is a view for explaining a second driving method of the sensor in FIGS. 2 and 3 according to an embodiment of the present invention.

FIG. 6 is a view for explaining a third driving method of the sensor in FIGS. 2 and 3 according to an embodiment of the present invention.

FIG. 7 is a view for explaining a fourth driving method of the sensor in FIGS. 2 to 3 according to an embodiment of the present invention.

FIG. 8 is a view for explaining a fifth driving method of the sensor in FIGS. 2 and 3 according to an embodiment of the present invention.

FIG. 9 is a plan view illustrating a portion of another embodiment of the sensor 10 in FIG. 1.

FIGS. 10A and 10B are plan views illustrating the sensor in FIG. 9, separated by layer.

FIG. 11 is a plan view illustrating a portion of a sensor according to another embodiment of the sensor 10 in FIG. 1.

FIGS. 12A and 12B are plan views illustrating the sensor in FIG. 11, separated by layer.

FIG. 13 is a plan view of a portion of a sensor according to another embodiment of the present invention.

FIG. 14 is a plan view illustrating only components disposed on a first layer of the sensor in FIG. 13.

FIG. 15 is a plan view illustrating only components disposed on a second layer of the sensor in FIG. 13.

FIG. 16 is a view for explaining a modified example of the sensor in FIGS. 13 to 15 according to another embodiment of the present invention.

### MODE FOR CARRYING OUT THE INVENTION

The present invention will now be described more fully with reference to the accompanying drawings, in which exemplary embodiments of the invention are shown. These embodiments are provided so that this disclosure will be thorough and complete, and will fully convey the concept of the invention to those skilled in art. The invention may, however, be embodied in many different forms and should not be construed as being limited to the embodiments set forth herein. Therefore, it will be understood that the embodiments disclosed in this specification include some variations without limitations to the shapes as illustrated in the figures. Also, the position or the arrangement of each component in the embodiment may be varied without departing from the spirit or scope of the invention. The preferred embodiments should be considered in descriptive sense only and not for purposes of limitation. Therefore, the scope of the invention is defined not by the detailed description of the invention but by the appended claims, and all differences within the scope will be construed as being included in the present invention. In the drawings, reference numerals refer to like elements throughout.

A touch input device according to various embodiments of the present document, which is an electronic device, may include at least one of, e.g., a smartphone, a tablet personal computer (PC), a display device for a vehicle, a mobile phone, a video phone, an e-book reader, a laptop personal computer (laptop PC), a netbook computer, a mobile medical device, a camera, or a wearable device. Here, the wearable device may include at least one of an accessory device (e.g., a watch, a ring, a bracelet, an anklet, a necklace, glasses, contact lenses, or a head-mounted-device (HMD)), a fabric or integrated garment (e.g., electronic clothing), a body attachable (e.g., a skin pad or tattoo), and abio-implantable device (e.g., an implantable circuit).

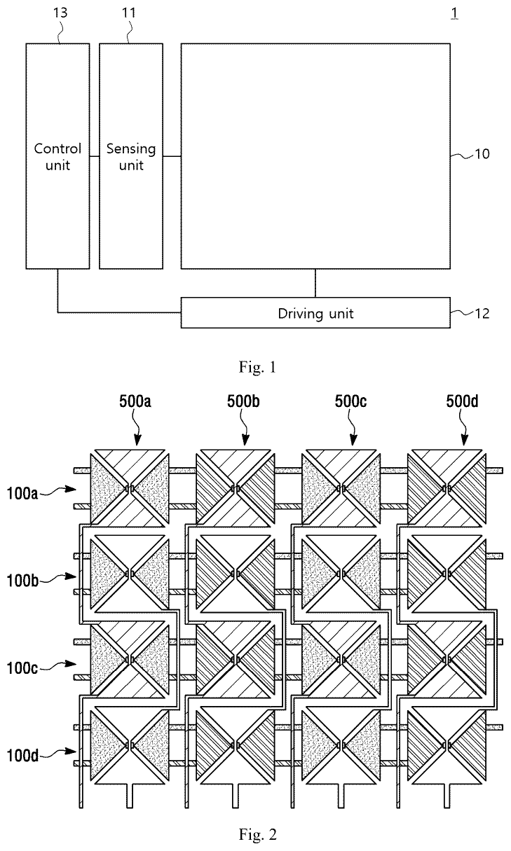

FIG. 1 is a schematic view illustrating a sensor and an input device including same according to an embodiment of the present invention.

Referring to FIG. 1, an input device 1 according to an embodiment of the present invention may include a sensor 10, a sensing unit 11, a driving unit 12, and a control unit 13.

The driving unit 12 applies a driving signal (or TX signal) to the sensor 10 by control of the control unit 13, and the sensing unit 11 receives a sensing signal (or RX signal) received from the sensor 10.

The driving unit 12 may supply the driving signal to each of driving electrodes of the sensor 10. The driving unit 12 may simultaneously supply predetermined driving signals to at least two or more driving electrodes or sequentially supply driving signals to respective driving electrodes according to the control of the control unit 13.

The sensing unit 11 receives reception signals output from a plurality of receiving electrodes of the sensor 10. Here, the reception signals may include not only information on capacitance variation amounts between the driving electrode and the receiving electrode, which are disposed adjacent to each other, but also various types of noise signals. Here, the noise signals may include LGM noise signals and display noise signals.

The sensing unit 11 may perform analog-to-digital conversion on the reception signals output from the plurality of receiving electrodes and output the converted signals. To this end, the sensing unit 11 may include an ADC.

Alternatively, the sensing unit 11 may subtract two signals among the reception signals output from the plurality of receiving electrodes to output subtracted signals and perform analog-to-digital conversion on the output subtracted signals to output converted signals. To this end, the sensing unit 11 may include a comparator and an ADC.

The control unit 13 may detect whether a touch is generated and/or a touch position based on a digital signal output from the sensing unit 11.

Although the sensing unit 11, the driving unit 12, and the control unit 13 are separated for convenience of description in FIG. 1, the embodiment of the present invention is not limited thereto. For example, at least one or two or more of the sensing unit 11, the driving unit 12, and the control unit 13 may be implemented as one module, unit, or chip, or the sensing unit 11, the driving unit 12, and the control unit 13 may be implemented as one module, unit, or chip.

The input device 1 in FIG. 1 may include a display panel. In this case, the sensor 10 may be disposed on the display panel or disposed in the display panel. Depending on cases, the sensor 10 may be disposed below the display panel. For example, the sensor 10 may be directly formed on an outer surface (e.g., a top surface of an upper substrate or a bottom surface of a lower substrate) or an inner surface (e.g., a bottom surface of the upper substrate or a top surface of the lower substrate) of the upper substrate and/or the lower substrate of the display panel. The sensor 10 may be coupled to the display panel to constitute the touch screen panel.

A plurality of scan lines (or gate lines) and a plurality of data lines may be disposed on the display panel. A subpixel may be disposed on an area in which the scan lines cross the data lines.

The display panel may include an active area on which a plurality of subpixels are disposed and an inactive area disposed outside the active area. The active area may constitute a display screen of the input device. The display screen may have a rectangular shape in which a vertical length is greater than a horizontal length.

The input device illustrated in FIG. 1 may include a gate driving circuit, a data driving circuit, and a display control unit for driving various signal lines disposed on the display panel in order to drive the display panel.

The gate driving circuit may be controlled by the display control unit and control a driving timing of the plurality of subpixels by sequentially outputting display scan signals to the plurality of scan lines disposed on the display panel.

The data driving circuit may receive image data from the display control unit and convert the received image data into an analog type data voltage. The data driving circuit may control each subpixel to emit brightness according to the image data by outputting the data voltage (Vdata) to each data line in accordance with a timing when the scan signal is applied through the scan line.

The display control unit may supply various control signals to the gate driving circuit and the data driving circuit and control operations of the gate driving circuit and the data driving circuit. The display control unit may be provided separately from or integrated with the control unit 13 in FIG. 1.

The sensor 10 may include electrodes each having a predetermined shape, and the predetermined electrodes may include a plurality of driving electrodes and a plurality of receiving electrodes. Although the plurality of driving electrodes and the plurality of receiving electrodes may be arranged in an orthogonal array, the embodiment of the present invention is not limited thereto. For example, the plurality of driving electrodes and the plurality of receiving electrodes may be arranged in various dimensional arrays and applied arrays such as diagonal, concentric circular, and three-dimensional random arrays. The number of the plurality of driving electrodes and the number of the plurality of sensing electrodes may be the same or different, and may vary depending on the input device according the embodiment.

The plurality of driving electrodes and the plurality of receiving electrodes may be disposed on the same layer (one layer) or on different double layers (two layers). Some of the plurality of driving electrodes may be disposed on a different layer from the others, and some of the plurality of receiving electrodes may be disposed on a different layer from the other. The plurality of driving electrodes and the plurality of receiving electrodes may each have a shape such as a rhombus shape, a diamond pattern shape, a circular shape, an elliptical shape, or another polygonal shape.

Hereinafter, various embodiments and driving methods of the sensor 10 according to an embodiment of the present invention will be described in detail with reference to the accompanying drawings.

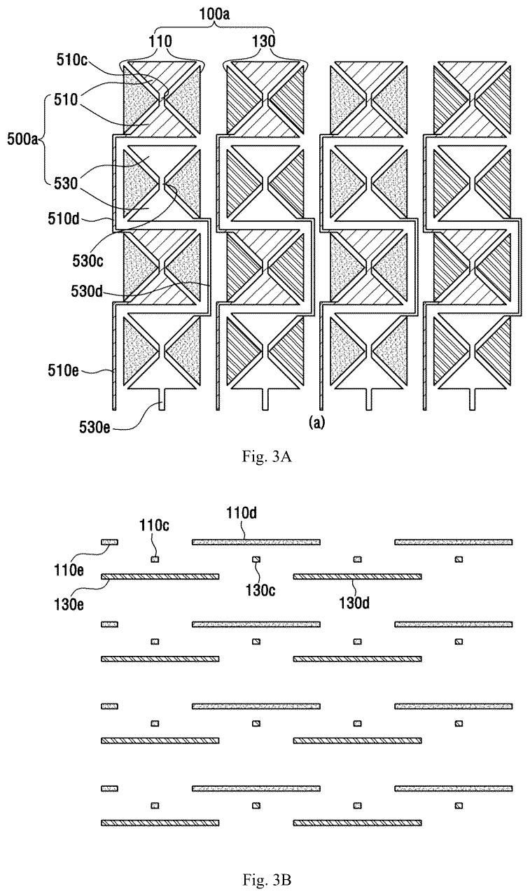

FIG. 2 is a plan view illustrating a portion of a sensor according to an embodiment of the sensor 10 in FIG. 1, and FIGS. 3A and 3B are plan views illustrating the sensor in FIG. 2, separated by layers.

Referring to FIGS. 2 to 3, the sensor according to an embodiment of the present invention may be disposed on a touch input area of the input device or a display area of the display panel contained in the input device.

The sensor according to an embodiment of the present invention may include a plurality of first electrodes 100a, 100b, 100c, and 100d and the plurality of second electrodes 500a, 500b, 500c, and 500d.

The plurality of first electrodes 100a, 100b, 100c, and 100d may be arranged along a first axial direction, and the plurality of second electrodes 500a, 500b, 500c, and 500d may be arranged along a second axial direction different from the first axial direction. Here, the second axial direction may be perpendicular to the first axial direction.

When the plurality of first electrodes 100a, 100b, 100c, and 100d are driving electrodes, the plurality of second electrodes 500a, 500b, 500c, and 500d may be receiving electrodes. Conversely, when the plurality of second electrodes 500a, 500b, 500c, and 500d are driving electrodes, the plurality of first electrodes 100a, 100b, 100c, and 100d may be receiving electrodes.

The plurality of first electrodes 100a, 100b, 100c, and 100d may include a first-a electrode 100a, a first-b electrode 100b, a first-c electrode 100c, and a first-d electrode 100d. The first-a electrode 100a, the first-b electrode 100b, the first-c electrode 100c, and the first-d electrode 100d may all have the same shape. Accordingly, a structure of the first-a electrode 100a will be described in detail, and descriptions of the first-b to first-d electrodes 100b, 100c, and 100d will be substituted with the description of the first-a electrode 100a.

The first-a electrode 100a includes first electrode pattern portions 110 and second electrode pattern portions 130. The first electrode pattern portions 110 and the second electrode pattern portions 130 may be alternately arranged with at least one of each along the first axis direction.

Each of the first electrode pattern portions 110 may include a pair of patterns that are symmetric with respect to the second axis. Each of the pair of patterns may have a triangular shape. The pair of patterns may be spaced apart from each other. The first-a electrode 100a may include a first connection pattern portion 110c for electrically connecting the pair of patterns, which are spaced apart from each other, of the first electrode pattern portion 110.

Each of the second electrode pattern portions 130 may include a pair of patterns that are symmetric with respect to the second axis. Each of the pair of patterns may have a triangular shape. The pair of patterns may be spaced apart from each other. The first-a electrode 100a may include a second connection pattern portion 130c for electrically connecting the pair of patterns, which are spaced apart from each other, of the second electrode pattern portion 130.

The first-a electrode 100a includes first electrode connection pattern portions 110d for electrically connecting the first electrode pattern portions 110 arranged alternately along the first axial direction. Also, the first-a electrode 100a may include a first control unit connection pattern portion 110e for connecting a control unit (not shown) with the first electrode pattern portion 110.

The first-a electrode 100a includes second electrode connection pattern portions 130d for electrically connecting the second electrode pattern portions 130 arranged alternately along the first axial direction. Also, the first-a electrode 100a includes a second control unit connection pattern portion 130e for connecting the control unit (not shown) with the second electrode pattern portion 130.

The plurality of second electrodes 500a, 500b, 500c, and 500d may include a second-a electrode 500a, a second-b electrode 500b, a second-c electrode 500c, and a second-d electrode 500d. The second-a electrode 500a, the second-b electrode 500b, the second-c electrode 500c, and the second-d electrode 500d may all have the same shape. Accordingly, a structure of the second-a electrode 500a will be described in detail, and descriptions of the second-b to second-d electrodes 500b, 500c, and 500d will be substituted with the description of the second-a electrode 500a.

The second-a electrode 500a includes third electrode pattern portions 510 and fourth electrode pattern portions 530. The third electrode pattern portions 510 and the fourth electrode pattern portions 530 are alternately arranged with at least one of each along the second axial direction.

Each of the third electrode pattern portions 510 may include a pair of patterns that are symmetric with respect to the first axis. Each of the pair of patterns may have a triangular shape. The pair of patterns may be spaced apart from each other. The second-a electrode 500a may include a third connection pattern portion 510c for electrically connecting the pair of patterns, which are spaced apart from each other, of the third electrode pattern portion 510.

Each of the fourth electrode pattern portions 530 may include a pair of patterns that are symmetric based on the first axis. Each of the pair of patterns may have a triangular shape. The pair of patterns may be spaced apart from each other. The second-a electrode 500a may include a fourth connection pattern portion 530c for electrically connecting the pair of patterns, which are spaced apart from each other, of the fourth electrode pattern portion 530.

The second-a electrode 500a includes third electrode connection pattern portions 510d for electrically connecting the third electrode pattern portions 510 arranged alternately along the second axial direction. Also, the second-a electrode 500a includes a third control unit connection pattern portion 510e for connecting the control unit (not shown) with the third electrode pattern portion 510.

The second-a electrode 500a includes fourth electrode connection pattern portions 530d for electrically connecting the fourth electrode pattern portions 530 arranged alternately along the second axial direction. Also, the second-a electrode 500a includes a fourth control unit connection pattern portion 530e for connecting the control unit (not shown) with the fourth electrode pattern portion 530.

Some components of the first-a electrode 100a may be disposed on a first layer, and the remaining components may be disposed on a second layer different from the first layer. For example, referring to FIGS. 3A and 3B, the first electrode pattern portions 110 and the second electrode pattern portions 130 of the first-a electrode 100a may be disposed on the first layer, and the connection pattern portions 110c, 110d, and 110e may be disposed on the second layer. The second layer is a different layer disposed above or below the first layer and is electrically insulated from the first layer. Additionally, all the components of the second-a electrode 500a may be disposed on the first layer. Although not shown in the drawings, all the components of the first-a electrode 100a may be disposed on either the first layer or the second layer, and some components of the second-a electrode 500a may be disposed on one of the first layer and the second layer, while the remaining components are disposed on the other layer. Alternatively, all the components of the first-a electrode 100a may be disposed on the first layer, and all the components of the second-a electrode 500a may be disposed on the second layer.

One of the first electrode pattern portions 110 of the first-a electrode 100a and one of the third electrode pattern portions 510 of the second-a electrode 500a may be disposed adjacent to each other. The pair of patterns of the first electrode pattern portion 110 may cross to the pair of patterns of the third electrode pattern portion 510.

One of the first electrode pattern portions of the first-b electrode 100b and one of the fourth electrode pattern portions 530 of the second-a electrode 500a may be disposed adjacent to each other. The pair of patterns of the first electrode pattern portion may cross the pair of patterns of the fourth electrode pattern portion 530.

One of the second electrode pattern portions 130 of the first-a electrode 100a and one of the third electrode pattern portions of the second-b electrode 500b may be disposed adjacent to each other. The pair of patterns of the second electrode pattern portion 130 may cross the pair of patterns of the third electrode pattern portion.

One of the second electrode pattern portions of the first-b electrode 100b and one of the fourth electrode pattern portions of the second-b electrode 500b may be disposed adjacent to each other. The pair of patterns of the second electrode pattern portion may cross the pair of patterns of the fourth electrode pattern portion.

Each of the plurality of first electrodes 100a, 100b, 100c, and 100d and the plurality of second electrodes 500a, 500b, 500c, and 500d may be implemented as a metal mesh.

Each of the connection pattern portions 110c, 110d, 110e, 130c, 130d, and 130e of the plurality of first electrodes 100a, 100b, 100c, and 100d disposed on the second layer may have a bar pattern shape extending in the first axial direction and include at least one conductive via. The conductive via may be disposed at one end or both ends of each of the connection pattern portions. Through the conductive via, the first electrode pattern portions 110 and the second electrode pattern portions 130, which are disposed on the first layer, may be electrically connected to each other.

At least a portion of each of the connection pattern portions 110c, 110d, 110e, 130c, 130d, and 130e may be disposed in the active area of the display panel (not shown).

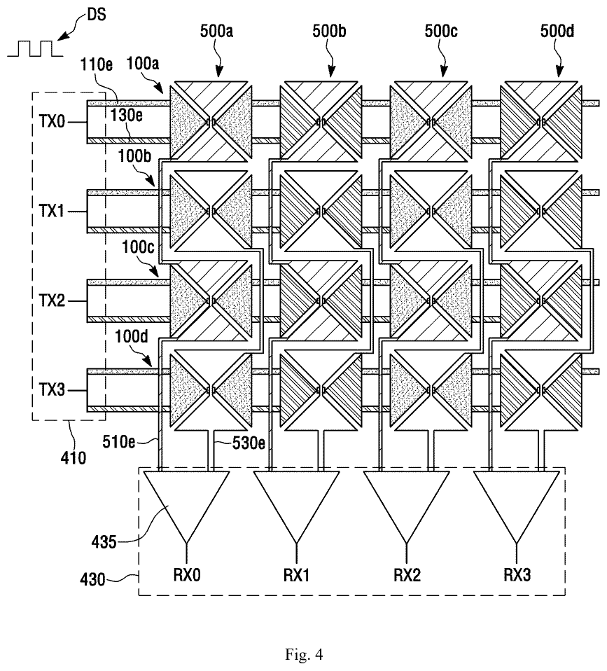

Hereinafter, various driving methods of the sensor according to an embodiment of the present invention in FIGS. 2 and 3 will be described with reference to FIGS. 4 to 8.

The various driving methods to be described below may be performed by the control unit (not shown) of the input device including the sensor according to an embodiment of the present invention in FIGS. 2 and 3.

The control unit (not shown) may apply a driving signal to at least one of the plurality of first electrodes 100a, 100b, 100c, and 100d and the plurality of second electrodes 500a, 500b, 500c, and 500d of the sensor, and receive a sensing signal from at least one of the other electrodes. Hereinafter, each driving method will be described in detail with reference to respective drawings.

FIG. 4 is a view for explaining a first driving method of the sensor in FIGS. 2 and 3 according to an embodiment of the present invention.

Referring to FIG. 4, in the first driving method, the plurality of first electrodes 100a, 100b, 100c, and 100d may be used as driving electrodes TX0, TX1, TX2, and TX3, and the plurality of second electrodes 500a, 500b, 500c, and 500d may be used as sensing electrodes RX0, RX1, RX2, and RX3. To this end, the control unit (not shown) applies a driving signal DS to the plurality of first electrodes 100a, 100b, 100c, and 100d, and receives a sensing signal from the plurality of second electrodes 500a, 500b, 500c, and 500d. Here, the driving signal DS may be a pulse-shaped signal or a sine wave-shaped signal.

The control unit (not shown) may apply the driving signal DS to at least one of the plurality of first electrodes 100a, 100b, 100c, and 100d. The control unit (not shown) may electrically connect the control unit connection pattern portions 110e and 130e of each of the first electrodes 100a, 100b, 100c, and 100d so as to apply the driving signal DS to the first and second electrode pattern portions 110 and 130 of each of the first electrodes 100a, 100b, 100c, and 100d, The control unit connection pattern portions 110e and 130e may be electrically connected through a driving unit 410 included in the control unit (not shown). The driving unit 410 may include switching elements capable of electrically short-circuiting or electrically opening the two control unit connection pattern portions 110e and 130e according to control of the control unit (not shown).

The control unit (not shown) may receive a sensing signal from at least one of the plurality of second electrodes 500a, 500b, 500c, and 500d.

The control unit (not shown) may include a sensing unit 430 electrically connected to control unit connection pattern portions 510e and 530e of each of the second electrodes 500a, 500b, 500c, and 500d. The sensing unit 430 may include a plurality of differential amplifiers 435. Each of the differential amplifiers 435 is electrically connected to the control unit connection pattern portions 510e and 530e of each of the second electrodes 500a, 500b, 500c, and 500d. Each of the differential amplifiers 435 differentially amplifies two sensing signals output from the two control unit connection pattern portions 510e and 530e and outputs the differentially amplified sensing signals. The control unit (not shown) may determine whether an object disposed on the sensor touches the sensor and a touch position of the object based on signals output from each of the differential amplifiers 435.

According to a first driving method illustrated in FIG. 4, each of the driving electrodes TX0, TX1, TX2, and TX3 is driven individually (single), and a differential signal is output from each of the sensing electrodes RX0, RX1, RX2, and RX3.

Thus, according to the first driving method illustrated in FIG. 4, since the differential signal is output from each of the second electrodes 500a, 500b, 500c, and 500d, a display-to-touch noise caused by the driving of the display panel and a noise caused by low ground mass (LGM) may be removed or improved.

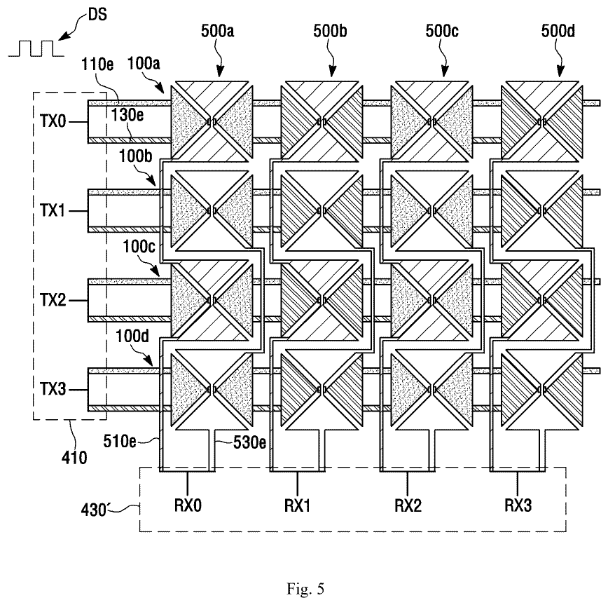

FIG. 5 is a view for explaining a second driving method of the sensor in FIGS. 2 and 3 according to an embodiment of the present invention.

Since the second driving method illustrated in FIG. 5 is different in only a sensing unit 430′ from the first driving method illustrated in FIG. 4, while the remaining components are the same, descriptions on the remaining components will be substituted with the above descriptions.

The sensing unit 430′ of FIG. 5 may include switching elements capable of electrically short-circuiting or electrically opening the two control unit connection pattern portions 510e and 530e according to the control of the control unit (not shown).

According to the second driving method illustrated in FIG. 5, the control unit (not shown) may electrically connect the two control unit connection pattern portions 110e and 130e of the driving unit 410 and electrically connect the two control unit connection pattern portions 510e and 530e of the sensing unit 430′ to use the sensor in FIGS. 2 and 3 according to the embodiment of the present invention in a single drive and single receive method. Alternatively, the sensor may be used as a pen detection sensor for receiving a pen signal emitted from a stylus pen.

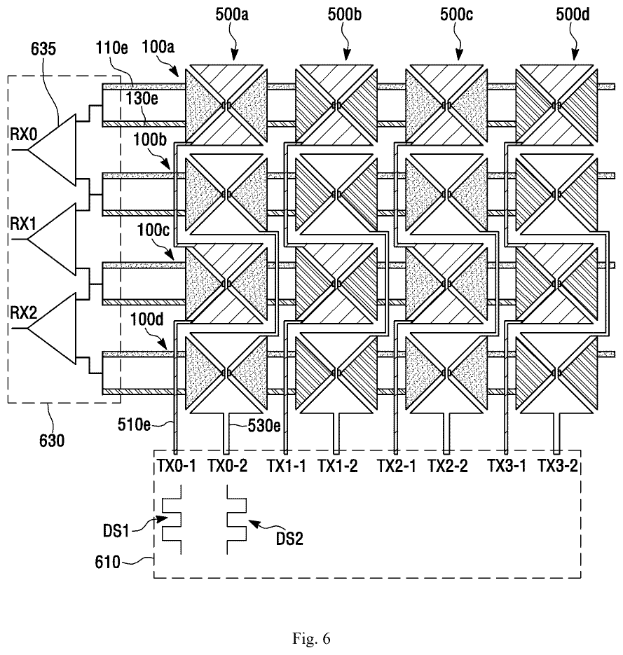

FIG. 6 is a view for explaining a third driving method of the sensor in FIGS. 2 and 3 according to an embodiment of the present invention.

Referring to FIG. 6, according to the third driving method, the plurality of first electrodes 100a, 100b, 100c, and 100d may be used as receiving electrodes RX0, RX1, and RX2, and the plurality of second electrodes 500a, 500b, 500c, and 500d may be used as driving electrodes TX0-1, TX0-2, TX1-1, TX1-2, TX2-1, TX2-2, TX3-1, and TX3-2. To this end, the control unit (not shown) applies first and second driving signals DS1 and DS2 to the plurality of second electrodes 500a, 500b, 500c, and 500d and receives sensing signals from the plurality of first electrodes 100a, 100b, 100c, and 100d. Here, each of the first and second driving signals DS1 and DS2 may be a pulse-shaped signal or a sine wave-shaped signal. The first driving signal DS1 and the second driving signal DS2 have a 180° phase difference from each other.

The control unit (not shown) may simultaneously apply the first and second driving signals DS1 and DS2 to at least one of the plurality of second electrodes 500a, 500b, 500c, and 500d.

A driving part 610 of the control unit (not shown) may be electrically connected to the two control unit connection pattern portions 510e and 530e of each of the second electrodes 500a, 500b, 500c, and 500d.

The control unit (not shown) may apply the first driving signal DS1 to the third electrode pattern portions 510 and the second driving signal DS2 to the fourth electrode pattern portions 530 of each of the second electrode 500a, 500b, 500c, and 500d through the driving part 610.

The control unit (not shown) may receive a sensing signal from at least one of the plurality of first electrodes 100a, 100b, 100c, and 100d through the sensing unit 630.

The sensing unit 630 of the control unit (not shown) may be electrically connected to the control unit connection pattern portions 110e and 130e of each of the first electrodes 100a, 100b, 100c, and 100d.

The sensing unit 630 of the control unit (not shown) may include switching elements capable of electrically short-circuiting or opening the control unit connection pattern portions 110e and 130e of each of the first electrodes 100a, 100b, 100c, and 100d. When the first and second driving signals DS1 and DS2 are applied to at least one of the second electrodes 500a, 500b, 500c, and 500d, the control unit (not shown) may control the switching elements to electrically short-circuit the control unit connection pattern portions 110e and 130e of each of the first electrodes 100a, 100b, 100c, and 100d.

The sensing unit 630 of the control unit (not shown) may include a plurality of differential amplifiers 635. Each of the differential amplifiers 635 differentially amplifies sensing signals respectively output from two of the plurality of first electrodes 500a, 500b, 500c, 500d and outputs the differentially amplified sensing signals. The control unit (not shown) may determine whether an object disposed on the sensor touches the sensor and a touch position of the object based on signals output from each of the differential amplifiers 635.

According to the third driving method illustrated in FIG. 6, each of the second electrodes 500a, 500b, 500c, and 500d is differentially driven, and a sensing signal is output from each of the first electrodes 100a, 100b, 100c, and 100d.

Thus, according to the third driving method illustrated in FIG. 6, since the first and second driving signals DS1 and DS2 are simultaneously applied to the respective second electrodes 500a, 500b, 500c, and 500d that are used as the driving electrodes TX0-1, TX0-2, TX1-1, TX1-2, TX2-1, TX2-2, TX3-1, and TX3-2, a noise (touch-to-display noise) caused by the driving of the sensor and transmitted to the display panel, e.g., a flicker phenomenon, may be improved. Also, since the driving signals may be simultaneously applied to all of the second electrodes 500a, 500b, 500c, and 500d, a touch driving time may be shortened, and thus, power consumption may be reduced. Also, a noise caused by LGM or the like may be removed or improved.

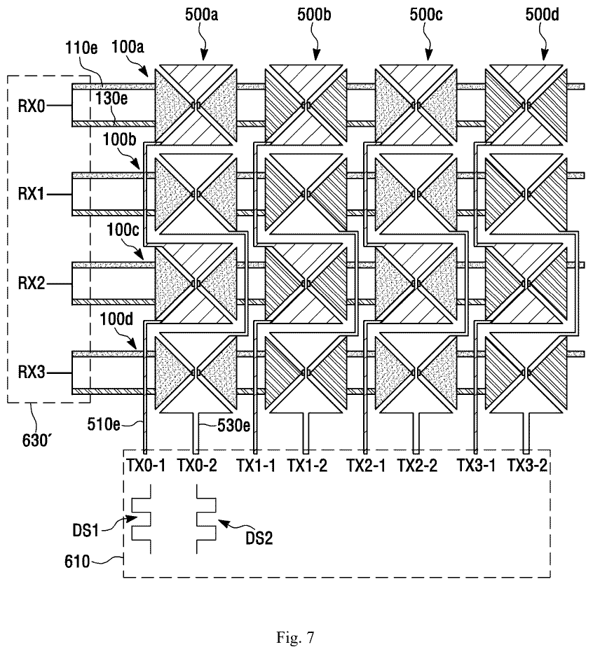

FIG. 7 is a view for explaining a fourth driving method of the sensor in FIGS. 2 to 3 according to an embodiment of the present invention.

Since the fourth driving method illustrated in FIG. 7 is different in only a sensing unit 630′ from the driving method illustrated in FIG. 6 while the remaining components are the same, descriptions on the remaining components will be substituted with the above descriptions.

The sensing unit 630′ of FIG. 7 may include switching elements capable of electrically short-circuiting or electrically opening the two control unit connection pattern portions 110e and 130e according to the control of the control unit (not shown).

In the fourth driving method shown in FIG. 7, the control unit (not shown) applies a first driving signal DS1 to the third electrode pattern portions 510 and a second driving signal DS2 to the fourth electrode pattern portions 530 of each of the second electrodes 500a, 500b, 500c, and 500d of the driving unit 610 and electrically connects the two control unit connection pattern portions 510e and 530e of the sensing unit 430′, so that each of the second electrodes 500a, 500b, 500c, and 500d is differentially driven, and each sensing signal is output from each of the first electrodes 100a, 100b, 100c, and 100d. Each sensing signal output from the first electrodes 100a, 100b, 100c, and 100d may include capacitance information, in which first capacitance information between the third electrode pattern portions 510 and the first electrodes 100a, 100b, 100c, and 100d and second capacitance information between the fourth electrode pattern portions 530 and the first electrodes 100a, 100b, 100c, and 100d are subtracted from one another.

Thus, since the first and second driving signals DS1 and DS2 are simultaneously applied to the second electrodes 500a, 500b, 500c, and 500d that serve as the driving electrodes TX0-1, TX0-2, TX1-1, TX1-2, TX2-1, TX2-2, TX3-1, and TX3-2 according to the fourth driving method of FIG. 7, the effect of the third driving method of FIG. 6 may be exhibited in the same manner.

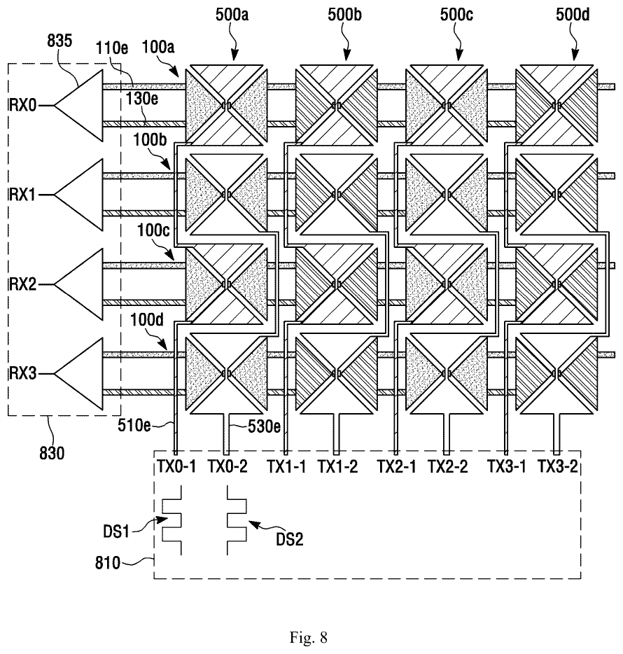

FIG. 8 is a view for explaining a fifth driving method of the sensor in FIGS. 2 to 3 according to an embodiment of the present invention.

Referring to FIG. 8, in the fifth driving method, the plurality of first electrodes 100a, 100b, 100c, and 100d may be used as the sensing electrodes RX0, RX1, and RX2, and the plurality of second electrodes 500a, 500b, 500c, and 500d may be used as the driving electrodes TX0-1, TX0-2, TX1-1, TX1-2, TX2-1, TX2-2, TX3-1, and TX3-2. To this end, the control unit (not shown) applies the first and second driving signals DS1 and DS2 to the plurality of second electrodes 500a, 500b, 500c, and 500d and receives the sensing signals from the plurality of first electrodes 100a, 100b, 100c, and 100d. Here, each of the first and second driving signals DS1 and DS2 may be a pulse-shaped signal or a sine wave-shaped signal. The first driving signal DS1 and the second driving signal DS2 have a 1800 phase difference from each other.

The control unit (not shown) may simultaneously apply the first and second driving signals DS1 and DS2 to at least one of the plurality of second electrodes 500a, 500b, 500c, and 500d.

A driving unit 810 of the control unit (not shown) may be electrically connected to the two control unit connection pattern portions 510e and 530e of each of the second electrodes 500a, 500b, 500c, and 500d.

The control unit (not shown) may apply the first driving signal DS1 to the third electrode pattern portions 510 and the second driving signal DS2 to the fourth electrode pattern portions 530 of each of the second electrode 500a, 500b, 500c, and 500d through the driving unit 810.

The control unit (not shown) may receive a sensing signal from at least one of the plurality of first electrodes 100a, 100b, 100c, and 100d through the sensing unit 830.

The sensing unit 830 of the control unit (not shown) may be electrically connected to the control unit connection pattern portions 110e and 130e of each of the first electrodes 100a, 100b, 100c, and 100d.

The sensing unit 830 may include a plurality of differential amplifiers 835. Each of the differential amplifier 835 is electrically connected to the control unit connection pattern portions 110e and 130e of each of the first electrode 100a, 100b, 100c, and 100d. Each of the differential amplifiers 835 differentially amplifies two sensing signals output from the two control unit connection pattern portions 110e and 130e and outputs the differentially amplified sensing signals. Based on the signals output from each differential amplifier 835, the control unit (not shown) may determine whether an object disposed on the sensor is touched and a touch position.

According to the fifth driving method illustrated in FIG. 8, each of the second electrodes 500a, 500b, 500c, and 500d is differentially driven, and the sensing signals output from each of the first electrodes 100a, 100b, 100c, and 100d are differentially output.

Thus, according to the fifth driving method illustrated in FIG. 8, all technical effects of both the first and second driving methods may be exhibited.

Specifically, since the first and second driving signals DS1 and DS2 are simultaneously applied to the respective second electrodes 500a, 500b, 500c, and 500d that are used as the driving electrodes TX0-1, TX0-2, TX1-1, TX1-2, TX2-1, TX2-2, TX3-1, and TX3-2, a touch to display noise caused by the driving of the sensor, e.g., the flicker phenomenon, may be improved. Also, since the driving signals may be simultaneously applied to all of the second electrodes 500a, 500b, 500c, and 500d, a touch driving time may be reduced, and thus, power consumption may be reduced. Also, a noise caused by LGM or the like may be removed or improved. Also, since differential signals are output from the respective first electrodes 100a, 100b, 100c, and 100d, a display to touch noise caused by driving of the display panel may be removed or improved.

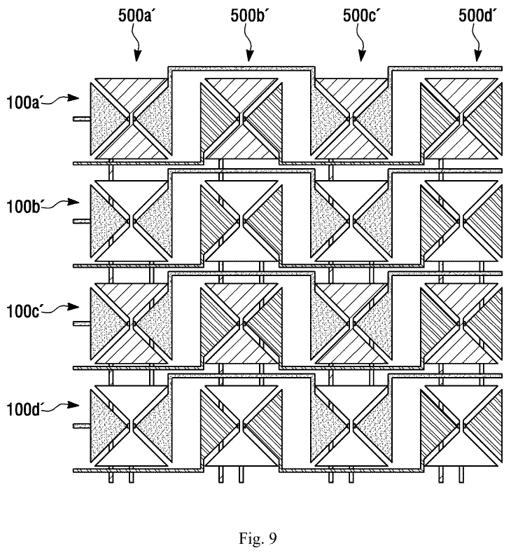

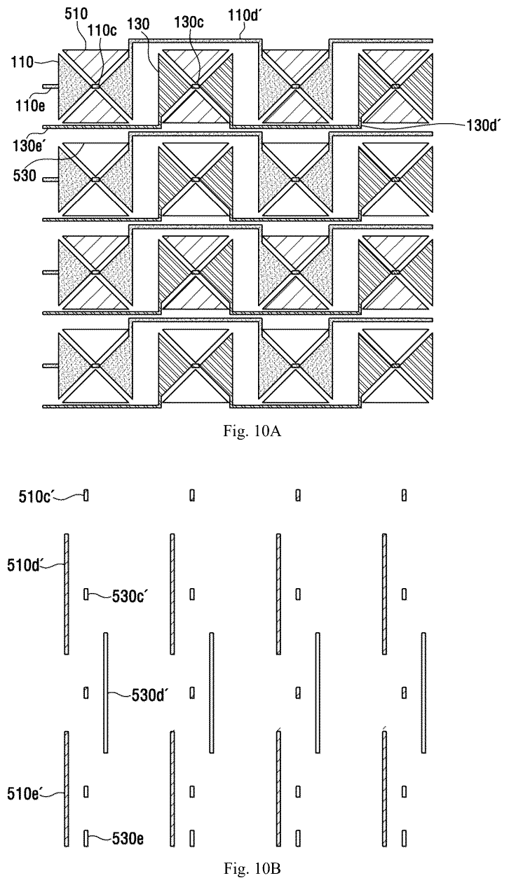

FIG. 9 is a plan view illustrating a portion of a sensor according to another embodiment of the sensor 10 in FIG. 1, and FIGS. 10A and 10B are plan views illustrating the sensor in FIG. 9, separated by layer.

The sensor according to another embodiment in FIGS. 9 to 10 includes a plurality of first electrodes 100a′, 100b′, 100c′, and 100d′ and a plurality of second electrodes 500a′, 500b′, 500c′, and 500d′.

In comparison with the sensor according to an embodiment in FIGS. 2 to 3, the sensor according to another embodiment in FIGS. 9 to 10 has: the same shapes in the first to fourth electrode pattern portions 110, 130, 510, and 530, the first to fourth connection pattern portions 110c, 130c, 510c, and 530c, and the control unit connection pattern portions 110e and 530e of the first and fourth electrode pattern portions 110 and 530; and different shapes in the electrode connection pattern portions 110d′, 130d′, 510d′, and 530d′ and the control unit connection pattern portions 130e′ and 510e′ of the second and third electrode pattern portions 130 and 510. Also, the patterns or pattern portions disposed on the first layer and the second layer, respectively, are also different from each other. Here, the patterns or pattern portions disposed on the first and second layers, respectively, may be variously modified based on design.

The sensor according to another embodiment in FIGS. 9 to 10 is one modified example of the sensor in FIGS. 2 to 3, which shows that shapes or positions of the patterns or pattern portions may be variously modified.

Similarly, the sensor according to another embodiment in FIGS. 9 to 10 may be driven using one of the first to fifth driving methods illustrated in FIGS. 4 to 8.

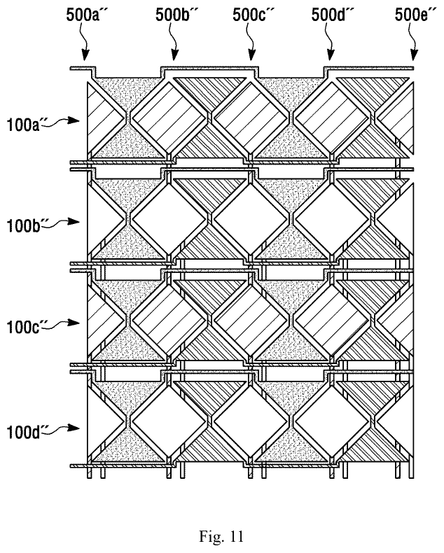

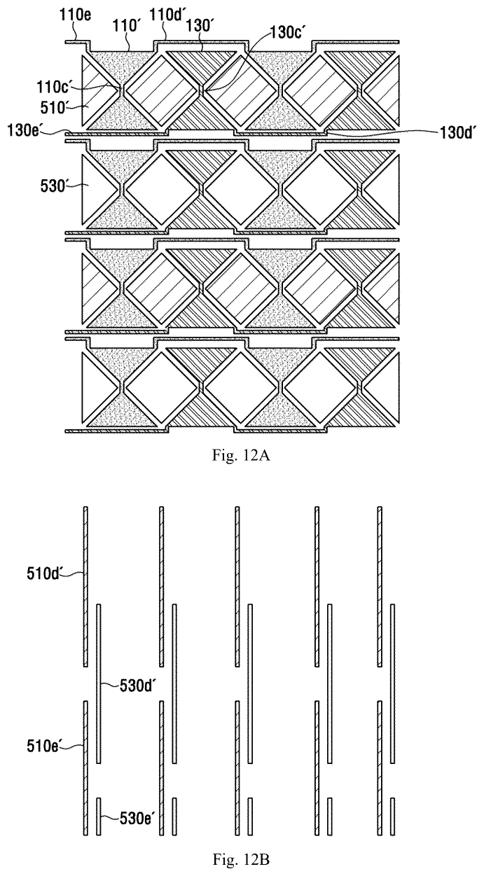

FIG. 11 is a plan view illustrating a portion of a sensor according to another embodiment of the sensor 10 illustrated in FIG. 1, and FIGS. 12A and 12B are plan views illustrating the sensor in FIG. 11, separated by layer.

The sensor according to another embodiment in FIGS. 11 to 12 includes a plurality of first electrodes 100a″, 100b″, 100c″, and 100d″ and a plurality of second electrodes 500a″, 500b″, 500c″, 500d″, and 500e″.

The plurality of first electrodes 100a″, 100b″, 100c″, and 100d″ may be arranged along the first axial direction, and the plurality of second electrodes 500a″, 500b″, 500c″, 500d″, and 500e″ may be arranged along the second axial direction perpendicular to the first axial direction.

When the plurality of first electrodes 100a″, 100b″, 100c″, and 100d″ serve as driving electrodes, the plurality of second electrodes 500a″, 500b″, 500c″, 500d″, and 500e″ may serve as sensing electrodes. In contrast, when the plurality of second electrodes 500a″, 500b″, 500c″, 500d″, and 500e″ serve as driving electrodes, the plurality of first electrodes 100a″, 100b″, 100c″, and 100d″ may serve as sensing electrodes.

The plurality of first electrodes 100a″, 100b″, 100c″, and 100d″ may include a first-a electrode 100a″, a first-b electrode 100b″, a first-c electrode 100c″, and a first-d electrode 100d″. The first-a electrode 100a″, the first-b electrode 100b″, the first-c electrode 100c″, and the first-d electrode 100d″ may have the same shape. Thus, a structure of the first-a electrode 100a″ will be described in detail, and descriptions on the first-b to first-d electrodes 100b″, 100c″, and 100d″ will be substitute with a description on the first-a electrode 100a″.

The first-a electrode 100a″ may include first electrode pattern portions 110′ and second electrode pattern portions 130′. The first electrode pattern portions 110′ and the second electrode pattern portions 130′ may be alternately arranged with at least one of each along the first axial direction.

Each of the first electrode pattern portions 110′ may include a pair of patterns that are symmetric based on the first axis. Each of the pair of patterns may have a triangular shape. The pair of patterns may be spaced apart from each other. The first-a electrode 100a″ may include a first connection pattern portion 110c′ for electrically connecting the pair of patterns, which are spaced apart from each other, of the first electrode pattern portion 110′. Here, the pair of patterns and the first connection pattern portion 110c′ may be integrated with each other.

Each of the first electrode pattern portions 110′ may be disposed between two adjacent third electrode pattern portions 510′ or two adjacent fourth electrode pattern portions 530′ in the first axial direction.

Each of the second electrode pattern portions 130′ may include a pair of patterns that are symmetric based on the first axis. Each of the pair of patterns may have a triangular shape. The pair of patterns may be spaced apart from each other. The first-a electrode 100a″ may include a second connection pattern portion 130c′ for electrically connecting the pair of patterns, which are spaced apart from each other, of the second electrode pattern portion 130′. Here, the pair of patterns and the second connection pattern portion 130c′ may be integrated with each other.

Each of the second electrode pattern portions 130′ may be disposed between two adjacent third electrode pattern portions 510′ or two adjacent fourth electrode pattern portions 530′ in the first axial direction.

The first-a electrode 100a″ includes electrode connection pattern portions 110d′ for electrically connecting the first electrode pattern portions 110′ that are alternately arranged along the first axial direction. Also, the first-a electrode 100a″ includes a control unit connection pattern portion 110e′ for connecting the first electrode pattern portions 110′ to the control unit (not shown).

The first-a electrode 100a″ includes electrode connection pattern portions 130d′ for electrically connecting the second electrode pattern portions 130′ that are alternately arranged along the first axial direction. Also, the first-a electrode 100a″ includes a control unit connection pattern portion 130e′ for connecting the second electrode pattern portions 130′ to the control unit (not shown).

The plurality of second electrodes 500a″, 500b″, 500c″, 500d″, and 500e″ may include a second-a electrode a 500a″, a second-b electrode 500b″, a second-c electrode 500c″, a second-d electrode 500d″, and a second-e electrode 500e″. The second-a electrode 500a″, the second-b electrode 500b″, the second-c electrode 500c″, the second-d electrode 500d″, and the second-e electrode 500e″ may have the same shape. Thus, a structure of the second-a electrode 500a″ will be described in detail, and descriptions on the second-b to second-e electrodes 500b″, 500c″, 500d″, and 500e″ will be substituted with a description on the second-a electrode 500a″.

The second-a electrode 500a″ includes third electrode pattern portions 510′ and fourth electrode pattern portions 530′. The third electrode pattern portions 510′ and the fourth electrode pattern portions 530′ are alternately arranged with at least one of each along the second axial direction.

Each of the third electrode pattern portions 510′ may have a triangular shape or a rhombic (diamond) shape. For example, among the plurality of third electrode pattern portions 510′, each of the patterns disposed at both ends in the first axial direction may have a triangular shape, and each of the remaining patterns may have a rhombic shape. Here, the triangular pattern may have an area that is a half of that of the rhombic pattern.

As a configuration feature, at least one third electrode pattern portion 510′ may be disposed between the first electrode pattern portion 110′ and the second electrode pattern portion 130′, which are adjacent to each other in the first axial direction.

Each of the fourth electrode pattern portions 530′ may have a triangular shape or a rhombic (diamond) shape. For example, among the plurality of fourth electrode pattern portions 530′, each of the patterns disposed at both ends in the first axial direction may have a triangular shape, and each of the remaining patterns may have a rhombic shape. Here, the triangular pattern may have an area that is a half of that of the rhombic pattern.

As a configuration feature, at least one fourth electrode pattern portion 530′ may be disposed between the first electrode pattern portion 110′ and the second electrode pattern portion 130′, which are adjacent to each other in the first axial direction.

The second-a electrode 500a″ includes electrode connection pattern portions 510d′ for electrically connecting the third electrode pattern portions 510′, which are arranged alternately along the second axial direction.

Also, the second-a electrode 500a″ includes a control unit connection pattern portion 510e′ for connecting the third electrode pattern portions 510′ to the control unit (not shown).

The second-a electrode 500a″ further includes electrode connection pattern portions 530d′ for electrically connecting the fourth electrode pattern portions 530′, which are also arranged alternately along the second axial direction. Also, the second-a electrode 500a″ includes a control unit connection pattern portion 530e′ for connecting the fourth electrode pattern portions 530′ to the control unit (not shown). All components of the first-a electrode 100a″ and some components of the second-a electrode 500a″ may be disposed on a first layer, while the remaining components of the second-a electrode 500a″ may be disposed on a second layer different from the first layer. For example, with reference to FIGS. 12A and 12B, the first electrode pattern portions 110′ and the second electrode pattern portions 130′ of the first-a electrode 100a″, the first and second connection pattern portions 110c′ and 130c′, the electrode connection pattern portions 110d′ and 130d′, and the control unit connection pattern portions 110e′ and 130e′ may be disposed on the first layer together with the third and fourth electrode pattern portions 510′ and 530′ of the second-a electrode 500a″, and the electrode connection pattern portions 510d′ and 530d′ and the controller connection pattern portions 510e′ and 530e′ of the second-a electrode 500a″ may be disposed on the second layer. The second layer is a different layer disposed above or below the first layer and is electrically insulated from the first layer.

The plurality of first electrodes 100a″, 100b″, 100c″, and 100d″ and the plurality of second electrodes 500a″, 500b″, 500c″, 500d″, and 500e″ may be implemented as a metal mesh.

The connection pattern portions 510d′, 530d′, 510e′, and 530e′ of the plurality of second electrodes 500a″, 500b″, 500c″, 500d″, and 500e″ disposed on the second layer may have a bar pattern shape extending in the second axial direction and include at least one conductive via. The conductive via may be disposed at one end or both ends of each of the connection pattern portions. Through the conductive via, the connection pattern portions 510d′, 530d′, 510e′, and 530e′ may be electrically connected to the third electrode pattern portions 510′ and the fourth electrode pattern portions 530′, which are disposed on the first layer.

The sensor illustrated in FIGS. 11 and 12 has an advantage of a simplified structure compared to the sensor illustrated in FIGS. 2 and 3. In particular, since a structure of the third and fourth electrode pattern portions 510′ and 530′ of the plurality of second electrodes 500a″, 500b″, 500c″, 500d″, and 500e″ is simplified, and the connection pattern portions 510c and 530c of the plurality of second electrodes 500a, 500b, 500c, and 500d in FIGS. 2 and 3 are not required, the plurality of second electrodes 500a″, 500b″, 500c″, 500d″, and 500e″ are more easily manufactured.

Also, the above-described first to fifth driving methods in FIGS. 4 to 8 may be directly applied to the sensor illustrated in FIGS. 11 to 12.

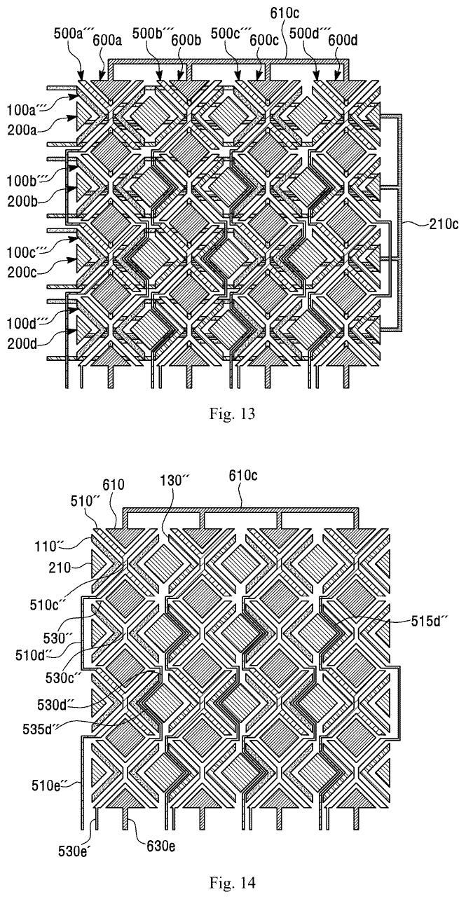

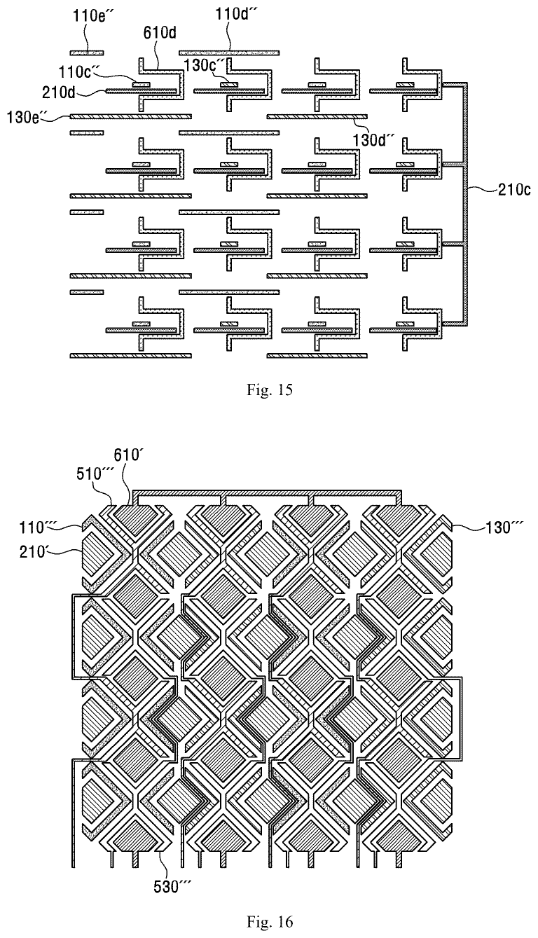

FIG. 13 is a plan view illustrating a portion of a sensor according to another embodiment of the present invention, FIG. 14 is a plan view illustrating only components disposed on a first layer of the sensor in FIG. 13, and FIG. 15 is a plan view illustrating only components disposed on a second layer of the sensor in FIG. 13.

Referring to FIGS. 13 to 15, the sensor according to an embodiment of the present invention may not only sense a touch of a conductive object or a finger, but also drive an external stylus pen and sense a pen signal emitted from the stylus pen.

Referring to FIGS. 13 to 15, the sensor according to an embodiment of the present invention includes a plurality of first electrodes 100a′″, 100b′″, 100c′″, and 100d′″, a plurality of second electrodes 500a′″, 500b′″, 500c′″, and 500d′″, a plurality of first pen electrodes 200a, 200b, 200c, and 200d, and a plurality of second pen electrodes 600a, 600b, 600c, and 600d.

The plurality of first electrodes 100a′″, 100b′″, 100c′″, and 100d′″ may be arranged along the first axial direction, and the plurality of second electrodes 500a′″, 500b′″, 500c′″, and 500d′″ may be arranged along the second axial direction different from the first axial direction. Here, the second axial direction may be perpendicular to the first axial direction.

When the plurality of first electrodes 100a′″, 100b′″, 100c′″, and 100d′″ serve as driving electrodes, the plurality of second electrodes 500a′″, 500b′″, 500c′″, and 500d′″ may serve as receiving electrodes. In contrast, when the plurality of second electrodes 500a′″, 500b′″, 500c′″, and 500d′″ serve as driving electrodes, the plurality of first electrodes 100a′″, 100b′″, 100c′″, and 100d′″ may serve as receiving electrodes.

The plurality of first electrodes 100a′″, 100b′″, 100c′″, and 100d′″ may include a first-a electrode 100a′″, first-b electrode 100b′″, first-c electrode 100c′″, and first-d electrode 100d′″. The first-a electrode 100a′″, the first-b electrode 100b′″, the first-c electrode 100c′″, and the first-d electrode 100d′″ may have the same shape. Thus, a structure of the first-a electrode 100a′″ will be described in detail, and descriptions on the first-b to first-d electrodes 100b′″, 100c′″, and 100d′″ will be substituted with a description on the first-a electrode 100a′″.

The first-a electrode 100a′″ includes first electrode pattern portions 110″ and second electrode pattern portions 130″. The first electrode pattern portions 110″ and the second electrode pattern portions 130″ are alternately arranged with at least one of each along the first axial direction.

Each of the first electrode pattern portions 110″ may include a pair of patterns that are symmetric based on the second axis. Each of the pair of patterns may have a triangular shape. The pair of patterns may be spaced apart from each other. Each of the pair of patterns may have a shape that surrounds at least a portion of the electrode pattern portion 210 of the plurality of first pen electrodes 200a, 200b, 200c, and 200d disposed adjacent to the pair of patterns.

The first-a electrode 100a′″ may include a first connection pattern portion 110c″ that electrically connects the pair of patterns, which are spaced apart from each other, of the first electrode pattern portion 110″.

Each of the second electrode pattern portions 130″ may include a pair of patterns that are symmetric based on the second axis. Each of the pair of patterns may have a triangular shape. The pair of patterns may be spaced apart from each other. Each of the pair of patterns may have a shape that surrounds at least a portion of the electrode pattern portion 210 of the plurality of first pen electrodes 200a, 200b, 200c, and 200d disposed adjacent to the pair of patterns.

The first-a electrode 100a′″ may include a second connection pattern portion 130c″ for electrically connecting the pair of patterns, which are spaced apart from each other, in the second electrode pattern portion 130″.

The first-a electrode 100a′″ includes first electrode connection pattern portions 110d″ for electrically connecting the first electrode pattern portions 110″ arranged along the first axial direction. Also, the first-a electrode 100a′″ includes a first control unit connection pattern portion 110e″ for connecting the control unit (not shown) to the first electrode pattern portions 110″.

The first-a electrode 100a′″ includes second electrode connection pattern portions 130d″ for electrically connecting the second electrode pattern portions 130″ arranged along the first axial direction. Also, the first-a electrode 100a′″ includes a second control unit connection pattern portion 130e″ for connecting the control unit (not shown) to the second electrode pattern portions 130″.

The plurality of second electrodes 500a′″, 500b′″, 500c′″, and 500d′″ may include a second-a electrode 500a′″, a second-b electrode 500b′″, a second-c electrode 500c′″, and a second-d electrode 500d′″. The second-a electrode 500a′″, the second-b electrode 500b′″, the second-c electrode 500c′″, and the second-d electrode 500d′″ may have the same shape. Thus, a structure of the second-a electrode 500a′″ will be described in detail, and descriptions on the second-b to second-d electrodes 500b′″, 500c′″, and 500d′″ will be substituted with a description of the second-a electrode 500a′″.

The second-a electrode 500a′″ may include third electrode pattern portions 510″ and fourth electrode pattern portions 530″. The third electrode pattern portions 510″ and the fourth electrode pattern portions 530″ may be alternately arranged with at least one of each along the second axial direction.

Each of the third electrode pattern portions 510″ may include a pair of patterns that are symmetric based on a first axis. Each of the pair of patterns may have a triangular shape. The pair of patterns may be spaced apart from each other. Each of the pair of patterns may have a shape that surrounds at least a portion of an electrode pattern portion 610 disposed adjacent to the pair of patterns among the plurality of second pen electrodes 600a, 600b, 600c, and 600d.

The second-a electrode 500a′″ may include a third connection pattern portion 510c″ for electrically connecting the pair of patterns, which are spaced apart from each other, of the third electrode pattern portions 510″.

Each of the fourth electrode pattern portions 530″ may include a pair of patterns that are symmetric based on the first axis. Each of the pair of patterns may have a triangular shape. The pair of patterns may be spaced apart from each other. Each of the pair of patterns may have a shape that surrounds at least a portion of an electrode pattern portion 610 disposed adjacent to the pair of patterns among the plurality of second pen electrodes 600a, 600b, 600c, and 600d.

The second-a electrode 500a′″ may include a fourth connection pattern portion 530c″ for electrically connecting the pair of patterns, which are spaced apart from each other, of the fourth electrode pattern portions 530″.

The second-a electrode 500a′″ may include electrode connection pattern portions 510d″ for electrically connecting the third electrode pattern portions 510″ arranged along the second axial direction. The second-a electrode 500a′″ may include a third control unit connection pattern portion 510e″ for connecting the control unit (not shown) to the third electrode pattern portions 510″.

The second-a electrode 500a′″ may include electrode connection pattern portions 530d″ for electrically connecting the fourth electrode pattern portions 530″ arranged along the second axial direction. The second-a electrode 500a′″ may include a fourth control unit connection pattern portion 530e″ for connecting a control unit (not shown) to the fourth electrode pattern portions 530″.

Some components of the first-a electrode 100a′″ may be disposed on a first layer, and the remaining components may be disposed on a second layer different from the first layer. Referring to FIGS. 14 and 15, for example, the first electrode pattern portions 110″ and the second electrode pattern portions 130″ of the first-a electrode 100a′″ may be disposed on the first layer, and the connection pattern portions 110c″, 110d″, 110e″, 130c″, 130d″, and 130e″ may be disposed on the second layer. The second layer is a different layer disposed above or below the first layer and is electrically insulated from the first layer.

All components of the second-a electrode 500a′″ may be disposed on the first layer. Although not shown in the drawings, all components of the first-a electrode 100a′″ may be disposed on either the first or the second layer, and some components of the second-a electrode 500a′″ may be disposed on either the first or second layer, while the remaining components are disposed on the other layer. Alternatively, all components of the first-a electrode 100a′″ may be disposed on the first layer, and all components of the second-a electrode 500a′″ may be disposed on the second layer.

One of the first electrode pattern portions 110″ of the first-a electrode 100a′″ and one of the third electrode pattern portions 510″ of the second-a electrode 500a′″ may be disposed adjacent to each other. The pair of patterns of the first electrode pattern portion 110″ may intersect with the pair of patterns of the third electrode pattern portion 510″. The pair of patterns of the first electrode pattern portion 110″ may be symmetrically disposed on both sides based on the third connection pattern portion 510c″.

One of the first electrode pattern portions of the first-b electrode 100b′″ and one of the fourth electrode pattern portions 530″ of the second-a electrode 500a′″ may be disposed adjacent to each other. The pair of patterns of the first electrode pattern portion may intersect with the pair of patterns of the fourth electrode pattern portion 530″. The pair of patterns of the first electrode pattern portion may be symmetrically disposed on both sides based on the fourth connection pattern portion 530c″.

One of the second electrode pattern portions 130″ of the first-a electrode 100a′″ and one of the third electrode pattern portions of the second-b electrode 500b′″ may be disposed adjacent to each other. The pair of patterns of the second electrode pattern portion 130″ may intersect with the pair of patterns of the third electrode pattern portion. The pair of patterns of the third electrode pattern portion 130″ may be symmetrically disposed on both sides based on the third connection pattern portion of the second-b electrode 500b′″.

One of the second electrode pattern portions of the first-b electrode 100b′″ and one of the fourth electrode pattern portions of the second electrode 2b 500b′″ may be disposed adjacent to each other. The pair of patterns of the second electrode pattern portion may intersect with the pair of patterns of the fourth electrode pattern portion. The pair of patterns of the respective second electrode pattern portion may be symmetrically disposed on both sides based on the fourth connection pattern portion of the second-b electrode 500b′″.

The plurality of first electrodes 100a′″, 100b′″, 100c′″, 100d′″ and the plurality of second electrodes 500a′″, 500b′″, 500c′″, 500d′″ may be implemented as a metal mesh.

The connection pattern portions 110c″, 110d″, 110e″, 130c″, 130d″, and 130e″ of the plurality of first electrodes 100a′″, 100b′″, 100c′″, and 100d′″ disposed on the second layer may have a bar pattern shape extending along the first axial direction and include at least one conductive via. The conductive via may be disposed at one end or both ends of each of the connection pattern portions. Through the conductive via, the connection pattern portions 110c″, 110d″, 110e″, 130c″, 130d″, and 130e″ may be electrically connected to the first electrode pattern portions 110″ and the second electrode pattern portions 130″ disposed on the first layer.

At least a portion of each of the connection pattern portions 110c″, 110d″, 110e″, 130c″, 130d″, and 130e″ may be disposed in an active area of a display panel (not shown).

Since the sensor illustrated in FIGS. 13 to 15 includes the plurality of first electrodes 100a′″, 100b′″, 100c′″, and 100d′″ and the plurality of second electrodes 500a′″, 500b′″, 500c′″, and 500d′″, the above-described first to fifth driving methods in FIGS. 4 to 8 may be directly applied, and corresponding effects may be exhibited.

The plurality of first pen electrodes 200a, 200b, 200c, and 200d may be arranged along the first axial direction, and the plurality of second pen electrodes 600a, 600b, 600c, and 600d may be arranged along the second axial direction different from the first axial direction. Here, the second axial direction may be perpendicular to the first axial direction.

The respective first pen electrodes 200a, 200b, 200c, and 200d may be disposed adjacent to the respective first electrode 100a′″, 100b′″, 100c′″, and 100d′″, and the respective second pen electrodes 600a, 600b, 600c, and 600d may be disposed adjacent to the respective second electrode 500a′″, 500b′″, 500c′″, and 500d′″.

Capacitive coupling may be formed between the respective first pen electrodes 200a, 200b, 200c, and 200d and the respective first electrodes 100a′″, 100b′″, 100c′″, and 100d′″, which are disposed adjacent to each other. Through the formed capacitive coupling, charge may be transferred between the respective first pen electrodes 200a, 200b, 200c, ad 200d and the respective first electrodes 100a′″, 100b′″, 100c′″, and 100d′″ disposed adjacent thereto, so that a current generated on one side (one of the respective first pen electrodes 200a, 200b, 200c, ad 200d and the respective first electrodes 100a′″, 100b′″, 100c′″, and 100d′″) may be transmitted to the other side. This principle of capacitive coupling may be used to drive an external stylus pen or receive a pen signal from the external stylus pen.

Similarly, the capacitive coupling may also be formed between the respective second pen electrodes 600a, 600b, 600c, and 600d and the respective second electrodes 500a′″, 500b′″, 500c′″, and 500d′″ that are disposed adjacent to each other. Through the formed capacitive coupling, charge may be transferred between the respective second pen electrodes 600a, 600b, 600c, and 600d and the respective second electrodes 500a′″, 500b′″, 500c′″, and 500d′″ disposed adjacent thereto, so that a current generated on one side (one of the respective second pen electrodes 600a, 600b, 600c, and 600d and the respective second electrodes 500a′″, 500b′″, 500c′″, and 500d′″) may be transmitted to the other side. This principle of capacitive coupling may be used to drive an external stylus pen or receive a pen signal from the external stylus pen.

The plurality of first pen electrodes 200a, 200b, 200c, and 200d or the plurality of second pen electrodes 600a, 600b, 600c, and 600d may serve as pen driving electrodes for driving an external stylus pen or as pen receiving electrodes for receiving a pen signal emitted from the external stylus pen. Here, when the externally located stylus pen is an active stylus pen, since the active stylus pen includes own battery and does not require external power for operation, the plurality of first pen electrodes 200a, 200b, 200c, and 200d or the plurality of second pen electrodes 600a, 600b, 600c, and 600d may serve only as pen receiving electrodes.

The plurality of first pen electrodes 200a, 200b, 200c, and 200d includes a first-a pen electrode 200a, a first-b pen electrode 200b, a first-c pen electrode 200c, and a first-d pen electrode 200d, and one ends of the first-a pen electrode 200a, the first-b pen electrode 200b, the first-c pen electrode 200c, and the first-d pen electrode 200d may be electrically connected to each other. Here, an inter-electrode connection pattern portion 210c may electrically connect the one ends.

The inter-electrode connection pattern portion 210c may allow the first-a pen electrode 200a, the first-b pen electrode 200b, the first-c pen electrode 200c, and the first-d pen electrode 200d to form a current loop through which a current (or an induced current) flows. The inter-electrode connection pattern portion 210c may be electrically connected to an electrode pattern portion disposed at one edge of the plurality of electrode pattern portions 210 of the first-a pen electrode 200a, electrically connected to an electrode pattern portion disposed at one edge of the plurality of electrode pattern portions of the first-b pen electrode 200b, electrically connected to an electrode pattern portion disposed at one edge of the plurality of electrode pattern portions of the first-c pen electrode 200c, and electrically connected to an electrode pattern portion disposed at one edge of the plurality of electrode pattern portions of the first-d pen electrode 200d.

The first-a pen electrode 200a, the first-b pen electrode 200b, the first-c pen electrode 200c, and the first-d pen electrode 200d may have the same shape. Hereinafter, a structure of the first-a pen electrode 200a will be described in detail, and descriptions on the first-b pen electrode 200b, the first-c pen electrode 200c0, and the first-d pen electrode 200d will be substituted with a description of the first-a pen electrode 200a.

The first-a pen electrode 200a may include a plurality of electrode pattern portions 210 arranged along the first axial direction. Each of the electrode pattern portions 210 may be surrounded by the first electrode pattern portion 110″ or the second electrode pattern portion 130″. Here, the electrode pattern portion 210 may be also referred to as a fifth electrode pattern portion.

Among the plurality of electrode pattern portions 210, two electrode pattern portions 210 disposed at both edges may be surrounded by one first electrode pattern portion 110″ or one second electrode pattern portion 130″. Each of the two electrode pattern portions 210 disposed at both the edges may have a triangular shape.

Among the plurality of electrode pattern portions 210, each of the remaining electrode pattern portions except for two electrode pattern portions 210 disposed at both edges may be surrounded by one first electrode pattern portion 110″ and one second electrode pattern portion 130″. One first electrode pattern portion and one second electrode pattern portion may be disposed on both sides, respectively, based on one of the remaining electrode pattern portions. Each of the remaining electrode pattern portions may have a rhombus or diamond shape. Here, each of the two electrode pattern portions 210 disposed at both the edges may be the same as a half of each of the remaining electrode pattern portions.

One portion 535d″ of the electrode connection pattern portion 530d″ of the plurality of second electrodes 500a′″, 500b′″, 500c′″, and 500d′″ may be disposed between at least one of the remaining electrode pattern portions and the first electrode pattern portion disposed adjacent thereto. Here, the portion 535d″ of the electrode connection pattern portion 530d″ may have a structure corresponding to an outer shape of the at least one electrode pattern portion.

One portion 515d″ of the electrode connection pattern portion 510d″ of the plurality of second electrodes 500a′″, 500b′″, 500c′″, and 500d′″ may be disposed between at least another of the remaining electrode pattern portions and the second electrode pattern portion disposed adjacent thereto. Here, the portion 515d″ of the electrode connection pattern portion 510d″ may have a structure corresponding to an outer shape of the at least another of the electrode pattern portions.

The first-a pen electrode 200a includes electrode connection pattern portions 210d for electrically connecting the plurality of electrode pattern portions 210 arranged along the first axial direction. Here, the electrode connection pattern portion 210d may be referred to as a fifth electrode connection pattern portion. The electrode connection pattern portions 210d may be disposed on a second layer that is different from the first layer on which the plurality of electrode pattern portions 210 are arranged. Here, the inter-electrode connection pattern portion 210c may be disposed together on the second layer.

The plurality of second pen electrodes 600a, 600b, 600c, and 600d includes a second-a pen electrode 600a, a second-b pen electrode 600b, a second-c pen electrode 600c, and a second-d pen electrode 600, and one ends of the second-a pen electrode 600a, the second-b pen electrode 600b, the second-c pen electrode 600c, and the second-d pen electrode 600d may be electrically connected. Here, the inter-electrode connection pattern portion 610c may electrically connect the one ends.

The inter-electrode connection pattern portion 610c may allow the second-a pen electrode 600a, the second-b pen electrode 600b, the second-c pen electrode 600c, and the second-d pen electrode 600d to form a current loop. The inter-electrode connection pattern portion 610c may be electrically connected to an electrode pattern portion disposed at one lateral edge among the plurality of electrode pattern portions 610 of the second-a pen electrode 600a, electrically connected to an electrode pattern portion disposed at one lateral edge among the plurality of electrode pattern portions of the second-b pen electrode 600b, electrically connected to an electrode pattern portion disposed at one lateral edge among the plurality of electrode pattern portions of the second-c pen electrode 600c, and electrically connected to an electrode pattern portion disposed at one lateral edge among the plurality of electrode pattern portions of the second-d pen electrode 600d.

The second-a pen electrode 600a, second-b pen electrode 600b, second-c pen electrode 600c, and second-d pen electrode 600d may have the same shape. Hereinafter, a structure of the second-a pen electrode 600a will be described in detail, and descriptions on the second-b pen electrode 600b, the second-c pen electrode 600c, and the second-d pen electrode 600d will be substituted with a description on the second-a pen electrode 600a.

The second-a pen electrode 600a includes a plurality of electrode pattern portions 610 arranged along the second axial direction. Each of the electrode pattern portions 610 may be surrounded by the third electrode pattern portion 510″ or the fourth electrode pattern portion 530″. Here, the electrode pattern portion 610 may be referred to as a sixth electrode pattern portion.

Among the plurality of electrode pattern portions 610, two electrode pattern portions 610 disposed at both edges may be surrounded by one third electrode pattern portion 510″ or one fourth electrode pattern portion 530″. Each of the two electrode pattern portions 610 disposed at both the edges may have a triangular shape.

Each of the remaining electrode pattern portions except for the two electrode pattern portions 610 disposed at both edges among the plurality of electrode pattern portions 610 may be surrounded by one third electrode pattern portion 510″ and one fourth electrode pattern portion 530″. One third electrode pattern portion and one fourth electrode pattern portion may be disposed on both sides based on one of the remaining electrode pattern portions. Each of the remaining electrode pattern portions may have a rhombus or diamond shape. Here, each of the two electrode pattern portions 610 disposed at both the edges may be the same as a half of each of the remaining electrode pattern portions.

The second-a pen electrode 600a includes electrode connection pattern portions 610d for electrically connecting the plurality of electrode pattern portions 610 arranged along the second axial direction. Here, the electrode connection pattern portions 610d may be referred to as sixth electrode connection pattern portions. The electrode connection pattern portions 610d may be disposed on a second layer that is different from the first layer on which the plurality of electrode pattern portions 610 are arranged. Here, the inter-electrode connection pattern portion 610c may be disposed on the first layer.

The plurality of first pen electrodes 200a, 200b, 200c, and 200d and the plurality of second pen electrodes 600a, 600b, 600c, and 600d may be implemented as a metal mesh.

The electrode connection pattern portions 210d of the plurality of first pen electrodes 200a, 200b, 200c, and 200d, which are disposed on the second layer, may have a bar pattern shape extending along the first axial direction, and the inter-electrode connection pattern portion 210c may have a bar pattern shape extending along both the first and second axial directions. Each of the electrode connection pattern portions may include at least one conductive via. The conductive via may be disposed at one end or both ends of each of the connection pattern portions. Through the conductive via, the electrode pattern portions 210 disposed on the first layer may be electrically connected.

The electrode connection pattern portions 610d of the plurality of second pen electrodes 600a, 600b, 600c, and 600d disposed on the second layer may have a bar pattern shape extending along the first and second axial directions. Each of the electrode connection pattern portions may include at least one conductive via. The conductive via may be disposed at one end or both ends of each of the connection pattern portions. Through the conductive via, the electrode connection pattern portions may be electrically connected to the electrode pattern portions 610 disposed on the first layer.

Here, at least a portion of the electrode connection pattern portions 610d of the plurality of second pen electrodes 600a, 600b, 600c, and 600d disposed on the second layer may be disposed between two electrode connection pattern portions 210d of the plurality of first pen electrodes 200a, 200b, 200c, and 200d.

At least a portion of each of the connection pattern portion 210c, 210d, and 610d may be disposed in an active area of a display panel (not shown).

Hereinafter, various methods for driving a control unit (not shown) of an input device or for sensing a pen signal from an external stylus pen using the sensor according to another embodiment of the present invention illustrated in FIGS. 13 to 15 will be described.

Table 1 below shows various combinations using the plurality of first electrodes 100a′″, 100b′″, 100c′″, and 100d′″, the plurality of second electrodes 500a′″, 500b′″, 500c′″, and 500d′″, the plurality of first pen electrodes 200a, 200b, 200c, and 200d, and the plurality of second pen electrodes 600a, 600b, 600c, and 600d. In the <Table 1> below, ‘1’ refers to the plurality of first electrodes 100a′″, 100b′″, 100c′″, and 100d′″, ‘2’ refers to the plurality of first pen electrodes 200a, 200b, 200c, and 200d, ‘3’ refers to the plurality of second electrodes 500a′″, 500b′″, 500c′″, and 500d′″, and ‘4’ refers to the plurality of second pen electrodes 600a, 600b, 600c, and 600d.

TABLE 1

| | | | Stylus | | | | | | | | | |
|---|---|---|---|---|---|---|---|---|---|---|---|---|
| | Finger Touch | | Operation | | | | Uplink signal | | | | | |
| | Operation | | Driving | | Sensing | | magnitude | | Downlink signal | | Stylus additional | |
| | Driving | Sensing | Major | Minor | X- | Y- | Major | Minor | magnitude | | channel | |
| No. | Tx | Rx | axis | axis | axis | axis | axis | axis | X-axis | Y-axis | Driving | Sensing |
| 1 | 1 | 3 | 2 | | 1 | 3 | Large | | Small | Small | Yes | No |
| 2 | 1 | 3 | 2 | | 1 | 4 | Large | | Small | Large | Yes | Yes |
| 3 | 1 | 3 | 2 | | 2 | 3 | Large | | Large | Small | Yes | Yes |
| 4 | 1 | 3 | 2 | | 2 | 4 | Large | | Large | Large | Yes | Yes |
| 5 | 1 | 3 | | 4 | 1 | 3 | | Large | Small | Small | Yes | No |
| 6 | 1 | 3 | | 4 | 1 | 4 | | Large | Small | Large | Yes | Yes |
| 7 | 1 | 3 | | 4 | 2 | 3 | | Large | Large | Small | Yes | Yes |
| 8 | 1 | 3 | | 4 | 2 | 4 | | Large | Large | Large | Yes | Yes |
| 9 | 1 | 3 | 2 | 4 | 1 | 3 | Large | Large | Small | Small | Yes | No |
| 10 | 1 | 3 | 2 | 4 | 1 | 4 | Large | Large | Small | Large | Yes | Yes |
| 11 | 1 | 3 | 2 | 4 | 2 | 3 | Large | Large | Large | Small | Yes | Yes |
| 12 | 1 | 3 | 2 | 4 | 2 | 4 | Large | Large | Large | Large | Yes | Yes |
| 13 | 1 | 3 | 1 | | 1 | 3 | Small | | Small | Small | No | No |
| 14 | 1 | 3 | 1 | | 1 | 4 | Small | | Small | Large | No | Yes |
| 15 | 1 | 3 | 1 | | 2 | 3 | Small | | Large | Small | No | Yes |
| 16 | 1 | 3 | 1 | | 2 | 4 | Small | | Large | Large | No | Yes |
| 17 | 1 | 3 | | 3 | 1 | 3 | | Small | Small | Small | No | No |
| 18 | 1 | 3 | | 3 | 1 | 4 | | Small | Small | Large | No | Yes |
| 19 | 1 | 3 | | 3 | 2 | 3 | | Small | Large | Small | No | Yes |
| 20 | 1 | 3 | | 3 | 2 | 4 | | Small | Large | Large | No | Yes |
| 21 | 1 | 3 | 1 | 3 | 1 | 3 | Small | Small | Small | Small | No | No |
| 22 | 1 | 3 | 1 | 3 | 1 | 4 | Small | Small | Small | Large | No | Yes |
| 23 | 1 | 3 | 1 | 3 | 2 | 3 | Small | Small | Large | Small | No | Yes |
| 24 | 1 | 3 | 1 | 3 | 2 | 4 | Small | Small | Large | Large | No | Yes |
| 25 | 1 | 3 | 2 | 3 | 1 | 3 | Large | Small | Small | Small | Yes | No |
| 26 | 1 | 3 | 2 | 3 | 1 | 4 | Large | Small | Small | Large | Yes | Yes |
| 27 | 1 | 3 | 2 | 3 | 2 | 3 | Large | Small | Large | Small | Yes | Yes |
| 28 | 1 | 3 | 2 | 3 | 2 | 4 | Large | Small | Large | Large | Yes | Yes |
| 29 | 1 | 3 | 1 | 4 | 1 | 3 | Small | Large | Small | Small | Yes | No |
| 30 | 1 | 3 | 1 | 4 | 1 | 4 | Small | Large | Small | Large | Yes | Yes |
| 31 | 1 | 3 | 1 | 4 | 2 | 3 | Small | Large | Large | Small | Yes | Yes |
| 32 | 1 | 3 | 1 | 4 | 2 | 4 | Small | Large | Large | Large | Yes | Yes |

Referring to <Table 1> above, in various combinations (No. 1 to No. 32), the plurality of first electrodes 100a′″, 100b′″, 100c′″, and 100d′″ and the plurality of second electrodes 500a′″, 500b′″, 500c′″, and 500d′″ sense a touch of an object such as a finger or a conductive object.

At least one or two of the plurality of first electrodes 100a′″, 100b′″, 100c′″, and 100d′″, the plurality of second electrodes 500a′″, 500b′″, 500c′″, and 500d′″, the plurality of first pen electrodes 200a, 200b, 200c, and 200d, and the plurality of second pen electrodes 600a, 600b, 600c, and 600d may serve as pen driving electrodes for driving an external stylus pen.

A current loop for driving the external stylus pen may be formed by using at least one or two of the plurality of first electrodes 100a′″, 100b′″, 100c′″, and 100d′″, the plurality of second electrodes 500a′″, 500b′″, 500c′″, and 500d′″, the plurality of first pen electrodes 200a, 200b, 200c, and 200d, and the plurality of second pen electrodes 600a, 600b, 600c, and 600d. An X-axis driving may be one kind of electrodes of the plurality of first electrodes 100a′″, 100b′″, 100c′″, and 100d′″ and the plurality of first pen electrodes 200a, 200b, 200c, and 200d, a Y-axis driving may be one kind of electrodes of the plurality of second electrodes 500a′″, 500b′″, 500c′″, and 500d′″ and the plurality of second pen electrodes 600a, 600b, 600c, and 600d. The stylus pen may be driven by the X-axis driving or the Y-axis driving or by both the X-axis driving and the Y-axis driving.

At least two of the plurality of first electrodes 100a′″, 100b′″, 100c′″, and 100d′″, the plurality of second electrodes 500a′″, 500b′″, 500c′″, and 500d′″, the plurality of first pen electrodes 200a, 200b, 200c, and 200d, and the plurality of second pen electrodes 600a, 600b, 600c, and 600d may serve as receiving electrodes for receiving a pen signal emitted from the external stylus pen. Since all of X-axis sensing and Y-axis sensing are required to sense the position of the external stylus pen by receiving the pen signal, two patterns of the plurality of first electrodes 100a′″, 100b′″, 100c′″, and 100d′″, the plurality of second electrodes 500a′″, 500b′″, 500c′″, and 500d′″, the plurality of first pen electrodes 200a, 200b, 200c, and 200d, and the plurality of second pen electrodes 600a, 600b, 600c, and 600d are used.

Specifically, the X-axis sensing may be one kind of electrodes of the plurality of first electrodes 100a′″, 100b′″, 100c′″, and 100d′″ and the plurality of first pen electrodes 200a, 200b, 200c, and 200d, a Y-axis sensing may be one kind of electrodes of the plurality of second electrodes 500a′″, 500b′″, 500c′″, and 500d′″ and the plurality of second pen electrodes 600a, 600b, 600c, and 600d.

In the <Table 1> above, the ‘magnitude of uplink signal’ represents a magnitude of the pen driving signal for driving the external stylus pen. When either one or both of the plurality of first pen electrodes 200a, 200b, 200c, 200d and the plurality of second pen electrodes 600a, 600b, 600c, 600d are directly used, the magnitude of the pen driving signal is relatively large. In contrast, when either one or both of the plurality of first electrodes 100a′″, 100b′″, 100c′″, and 100d′″ and the plurality of second electrodes 500a′″, 500b′″, 500c′″, and 500d′″ are used, the pen driving signal applied to the plurality of first electrodes 100a′″, 100b′″, 100c′″, and 100d′″ and/or the plurality of second electrodes 500a′″, 500b′″, 500c′″, and 500d′″ is transferred to the plurality of first pen electrodes 200a, 200b, 200c, and 200d and/or the plurality of second pen electrodes 600a, 600b, 600c, and 600d via capacitive coupling. As a result, the magnitude of the pen driving signal flowing through the plurality of first pen electrodes 200a, 200b, 200c, and 200d and/or the plurality of second pen electrodes 600a, 600b, 600c, and 600d is relatively small.

The term ‘downlink signal magnitude’ represents an amplitude of the pen signal received from an external stylus pen. When either one or both of the plurality of first pen electrodes 200a, 200b, 200c, and 200d and the plurality of second pen electrodes 600a, 600b, 600c, and 600d are directly used, the magnitude of the received pen signal is relatively large. In contrast, when either one or both of the plurality of first electrodes 100a′″, 100b′″, 100c′″, and 100d′″ and the plurality of second electrodes 500a′″, 500b′″, 500c′″, and 500d′″ are used, a pen signal induced at the plurality of first pen electrodes 200a, 200b, 200c, and 200d and/or the plurality of second pen electrodes 600a, 600b, 600c, and 600d is transferred to the plurality of first electrodes 100a′″, 100b′″, 100c′″, and 100d′″ and/or the plurality of second electrodes 500a′″, 500b′″, 500c′″, and 500d′″ through capacitive coupling. Accordingly, the magnitude of the pen signal flowing through the plurality of first electrodes 100a′″, 100b′″, 100c′″, and 100d′″ and/or the plurality of second electrodes 500a′″, 500b′″, 500c′″, and 500d′″ is relatively small.

The term ‘stylus additional channel’ represents whether an additional channel, separate from the channels used for touch sensing, needs to be provided in the control unit (not shown) for driving and/or receiving signals from the external stylus pen. When the driving or sensing of the stylus pen is performed using the plurality of first pen electrodes 200a, 200b, 200c, and 200d and/or the plurality of second pen electrodes 600a, 600b, 600c, and 600d, the plurality of first pen electrodes 200a, 200b, 200c, and 200d and/or the plurality of second pen electrodes 600a, 600b, 600c, and 600d need to be electrically connected to the control unit (not shown). Thus, the control unit (not shown) needs to include a plurality of channels for the plurality of first pen electrodes 200a, 200b, 200c, and 200d and/or the plurality of second pen electrodes 600a, 600b, 600c, and 600d. When the plurality of first pen electrodes 200a, 200b, 200c, and 200d and/or the plurality of second pen electrodes 600a, 600b, 600c, and 600d are not used during the driving or sensing of the stylus pen, the plurality of channels are not required.

Thus, the sensor illustrated in FIGS. 13 to 15 may be driven by any one of the first to fifth driving methods shown in FIGS. 4 to 8, and may drive the external stylus pen, e.g., a passive stylus pen, or receive a pen signal from the external stylus pen, e.g., an active or passive stylus pen.

FIG. 16 is a view illustrating a modified example of the sensor according to another embodiment of the present invention in FIGS. 13 to 15, specifically illustrating a modified example of the plan view in FIG. 14.

Referring to FIG. 16, the sensor according to the modified example is structurally different from the sensor in FIGS. 13 to 15 in that the sensor includes a first electrode pattern portion 110′″ and a second electrode pattern portion 130′″ disposed at both edges along the first axial direction of the first electrode, a third electrode pattern portion 510′″ and a fourth electrode pattern portion 530′″ disposed at both edges along the second-axial direction of the second electrode, and electrode pattern portions 210′ of the first pen electrode and electrode pattern portions 610′ of the second pen electrode.

In FIG. 16, all of the first electrode pattern portion 110′″, the second electrode pattern portion 130′″, the third electrode pattern portion 510′″, the fourth electrode pattern portion 530′″, the electrode pattern portion 210′ of the first pen electrode, and the electrode pattern portion 610′ of the second pen electrode are illustrated differently from those in FIG. 14. However, at least one of the first electrode pattern portion 110′″, the second electrode pattern portion 130′″, the third electrode pattern portion 510′″, the fourth electrode pattern portion 530′″, the electrode pattern portion 210′ of the first pen electrode, and the electrode pattern portion 610′ of the second pen electrode may be implemented as illustrated in FIG. 16, while the remaining portions may have the same structure as illustrated in FIG. 14.

Referring to FIG. 16, at least one of the first electrode pattern portion 110′″, the second electrode pattern portion 130′″, the third electrode pattern portion 510′″, and the fourth electrode pattern portion 530′″ may have a shape corresponding to a portion of a rhombus. For example, at least one of the first electrode pattern portion 110′″, the second electrode pattern portion 130′″, the third electrode pattern portion 510′″, and the fourth electrode pattern portion 530′″ may have a pentagonal diamond shape.

At least one of the electrode pattern portion 210′ of the first pen electrode and the electrode pattern portion 610′ of the second pen electrode may also have a shape corresponding to a portion of a rhombus. For example, at least one of the electrode pattern portion 210′ of the first pen electrode and the electrode pattern portion 610′ of the second pen electrode may have a pentagonal diamond shape.

The first electrode pattern portion 110′″, the second electrode pattern portion 130′″, the third electrode pattern portion 510′″, and the fourth electrode pattern portion 530′″ may surround at least a portion of the electrode pattern portion 210′ of the first pen electrode or the electrode pattern portion 610′ of the second pen electrode.

Features, structures, and effects described in the above embodiments are incorporated into at least one embodiment of the present disclosure, but are not limited to only one embodiment. Moreover, features, structures, and effects exemplified in one embodiment can easily be combined and modified for another embodiment by those skilled in the art. Therefore, these combinations and modifications should be construed as falling within the scope of the present disclosure.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A sensor comprising:
a first electrode comprising first electrode pattern portions and second electrode pattern portions, which are alternately arranged with at least one of each along a first axial direction, a first electrode connection pattern portion configured to electrically connect the first electrode pattern portions, and a second electrode connection pattern portion configured to electrically connect the second electrode pattern portions; and
a second electrode comprising third electrode pattern portions and fourth electrode pattern portions, which are alternately arranged with at least one of each along a second axial direction, a third electrode connection pattern portion configured to electrically connect the third electrode pattern portions, and a fourth electrode connection pattern portion configured to electrically connect the fourth electrode pattern portions.

2. The sensor of claim 1, wherein at least one of the third electrode pattern portions or at least one of the fourth electrode pattern portions is disposed between the first electrode pattern portion and the second electrode pattern portion, which are adjacent to each other in the first axial direction.

3. (canceled)

4. The sensor of claim 1, wherein the first electrode further comprises:
a first control unit connection pattern portion electrically connected to a first electrode pattern portion disposed at one edge among the first electrode pattern portions; and a second control unit connection pattern portion electrically connected to a second electrode pattern portion disposed at one edge among the second electrode pattern portions, and
the second electrode further comprises: a third control unit connection pattern portion electrically connected to a third electrode pattern portion disposed at one edge among the first electrode pattern portions; and a fourth control unit connection pattern portion electrically connected to a fourth electrode pattern portion disposed at one edge among the fourth electrode pattern portions,
wherein, when at least one driving signal is received through the first and second control unit connection pattern portions, a sensing signal is output through the third and fourth control unit connection pattern portions, or
when at least one driving signal is received through the third and fourth control unit connection pattern portions, a sensing signal is output through the first and second control unit connection pattern portions.

5. (canceled)

6. The sensor of claim 4, wherein the at least one driving signal comprises a first driving signal and a second driving signal, and
the second driving signal has a phase inverted by 180° relative to that of the first driving signal.

7. The sensor of claim 1, further comprising:
a first pen electrode disposed adjacent to the first electrode to form a first capacitive coupling with the first electrode; and
a second pen electrode disposed adjacent to the second electrode to form a second capacitive coupling with the second electrode,
wherein each of the first electrode, the second electrode, the first pen electrode, and the second pen electrode is provided in plurality,
one ends of the plurality of first pen electrodes are electrically connected to each other, and
one ends of the plurality of second pen electrodes are electrically connected to each other.

8. The sensor of claim 7, wherein the first pen electrode comprises fifth electrode pattern portions arranged along the first axial direction and fifth electrode connection pattern portions configured to electrically connect the fifth electrode pattern portions, and
the second pen electrode comprises sixth electrode pattern portions arranged along the second axial direction and sixth electrode connection pattern portions configured to electrically connect the sixth electrode pattern portions.

9. The sensor of claim 8, wherein the first to sixth electrode pattern portions are disposed together on a first layer,
at least one of the fifth electrode pattern portions is disposed between the first electrode pattern portion and the second electrode pattern portion,
at least one of the sixth electrode pattern portions is disposed between the third electrode pattern portion and the fourth electrode pattern portion,
wherein the third and fourth electrode connection pattern portions are disposed on the first layer, and
the first and second electrode connection pattern portions and the fifth and sixth electrode connection pattern portions are disposed on a second layer that is electrically insulated from the first layer.

10. (canceled)

11. The sensor of claim 9, further comprising:
a first pattern portion configured to electrically connect the one ends of the plurality of first pen electrodes; and
a second pattern portion configured to electrically connect the one ends of the plurality of second pen electrodes,
wherein the first pattern portion is disposed on the second layer, and the second pattern portion is disposed on the first layer.

12. The sensor of claim 9, wherein at least one of the third electrode connection pattern portions is disposed between one of the first and second electrode pattern portions and the fifth electrode pattern portion, and has a portion corresponding to an outer shape of the fifth electrode pattern portion, and
wherein at least one of the fourth electrode connection pattern portions is disposed between one of the first and second electrode pattern portions and the fifth electrode pattern portion, and has a portion corresponding to an outer shape of the fifth electrode pattern portion.

13. (canceled)

14. The sensor of claim 8, wherein, among the fifth electrode pattern portions, each of two fifth electrode pattern portions disposed at both edges in the first axial direction has a triangular shape or a pentagonal diamond shape, while each of the remaining fifth electrode pattern portions except for the two fifth electrode pattern portions has a rhombus shape, and
among the sixth electrode pattern portions, each of two sixth electrode pattern portions disposed at both edges in the second axial direction has a triangular shape or a pentagonal diamond shape, while each of the remaining sixth electrode pattern portions except for the two sixth electrode pattern portions has a rhombus shape.

15. The sensor of claim 8, wherein, among the fifth electrode pattern portions, each of two fifth electrode pattern portions disposed at both edges in the first axial direction has a shape corresponding to a portion of a shape of each of the remaining fifth electrode pattern portions except for the two fifth electrode pattern portions,
at least one of the first and second electrode pattern portions surrounds at least a portion of the two fifth electrode pattern portions,
among the sixth electrode pattern portions, each of two sixth electrode pattern portions disposed at both edges in the second axial direction has a shape corresponding to a portion of a shape of each of the remaining sixth electrode pattern portions except for the two sixth electrode pattern portions, and
at least one of the third and fourth electrode pattern portions surrounds at least a portion of the two sixth electrode pattern portions.

16. The sensor of claim 7, wherein each of the plurality of first pen electrodes comprises a fifth control unit connection pattern portion connected to one end thereof, or each of the plurality of second pen electrodes comprises a sixth control unit connection pattern portion connected to one end thereof,
wherein a pen driving signal is received by one kind of electrode among the plurality of first pen electrodes and the plurality of second pen electrodes, and
a pen sensing signal induced by a pen signal emitted from a stylus pen through the plurality of first pen electrodes and the plurality of second pen electrodes is generated.

17. An input device comprising a sensor and a control unit configured to control the sensor, wherein the sensor comprises:
a first electrode comprising first electrode pattern portions and second electrode pattern portions, which are alternately arranged with at least one of each along a first axial direction, a first electrode connection pattern portion configured to electrically connect the first electrode pattern portions, and a second electrode connection pattern portion configured to electrically connect the second electrode pattern portions; and
a second electrode comprising third electrode pattern portions and fourth electrode pattern portions, which are alternately arranged with at least one of each along a second axial direction, a third electrode connection pattern portion configured to electrically connect the third electrode pattern portions, and a fourth electrode connection pattern portion configured to electrically connect the fourth electrode pattern portions,
wherein the control unit comprises:
a driving unit configured to apply at least one driving signal to one of the first electrode and the second electrode;
a sensing unit configured to receive at least one sensing signal from one of the first electrode and the second electrode; and
a control unit configured to determine a touch position based on a signal output from the sensing unit.

18. The input device of claim 17, wherein the first electrode further comprises: a first control unit connection pattern portion electrically connected to a first electrode pattern portion disposed at one edge among the first electrode pattern portions; and a second control unit connection pattern portion electrically connected to a second electrode pattern portion disposed at one edge among the second electrode pattern portions, and
the second electrode further comprises: a third control unit connection pattern portion electrically connected to a third electrode pattern portion disposed at one edge among the first electrode pattern portions; and a fourth control unit connection pattern portion electrically connected to a fourth electrode pattern portion disposed at one edge among the fourth electrode pattern portions,
wherein, when the at least one driving signal is applied through the first and second control unit connection pattern portions, the at least one sensing signal is output through the third and fourth control unit connection pattern portions, or
when at least one driving signal is applied through the third and fourth control unit connection pattern portions, the at least one sensing signal is output through the first and second control unit connection pattern portions.

19. (canceled)

20. The input device of claim 18, wherein the at least one driving signal comprises a first driving signal and a second driving signal, and the second driving signal has a phase inverted by 180° relative to that of the first driving signal.

21. The input device of claim 18, wherein the driving unit comprises a switching element configured to electrically short-circuit or electrically open the first and second control unit connection pattern portions, and
the sensing unit comprises a differential amplifier that is electrically connected to the third and fourth control unit connection pattern portions and differentially amplifies two sensing signals output from the third and fourth control unit connection pattern portions.

22. The input device of claim 18, wherein the driving unit comprises a switching element configured to electrically short-circuit or electrically open the first and second control unit connection pattern portions, and
the sensing unit comprises a switching element configured to electrically short-circuit or electrically open the third and fourth control unit connection pattern portions.

23. The input device of claim 18, wherein the driving unit applies a first driving signal to the third control unit connection pattern portion and a second driving signal to the fourth control unit connection pattern portion, and
the sensing unit comprises a differential amplifier configured to differentially amplify two sensing signals output from the first electrode and another first electrode disposed adjacent to the first electrode.

24. The input device of claim 18, wherein the driving unit applies a first driving signal to the third control unit connection pattern portion and a second driving signal to the fourth control unit connection pattern portion, and
the sensing unit comprises a switching element configured to electrically short-circuit or electrically open the first and second control unit connection pattern portions.

25. The input device of claim 18, wherein the driving unit applies a first driving signal to the third control unit connection pattern portion and a second driving signal to the fourth control unit connection pattern portion, and
the sensing unit comprises a differential amplifier that is electrically connected to the first and second control unit connection pattern portions and differentially amplifies two sensing signals output from the third and fourth control unit connection pattern portions.

26. The input device of claim 17, wherein the sensor comprises:
a first pen electrode disposed adjacent to the first electrode to form a first capacitive coupling with the first electrode; and
a second pen electrode disposed adjacent to the second electrode to form a second capacitive coupling with the second electrode,
wherein each of the first electrode, the second electrode, the first pen electrode, and the second pen electrode is provided in plurality,
one ends of the plurality of first pen electrodes are electrically connected to each other, one ends of the plurality of second pen electrodes are electrically connected to each other,
the control unit applies a pen driving signal to at least one of the first electrode, the second electrode, the first pen electrode, and the second pen electrode,
the control unit receives a pen sensing signal from at least two of the first electrode, the second electrode, the first pen electrode, and the second pen electrode, and
the control unit determines a touch position of an object and a position of a stylus pen based on a signal output from the sensing unit, and
wherein one of the first pen electrode and the second pen electrode comprises a control unit connection pattern portion configured to electrically connect the electrode with the control unit, and
wherein one of the first pen electrode and the second pen electrode comprises a control unit connection pattern portion configured to electrically connect the electrode with the control unit.

27. (canceled)
